(19) United States
(12) Patent Application Publication
(10) Pub. No.: US 2025/0224327 A1
(43) Pub. Date: Jul. 10, 2025

(54) NONLINEAR OPTICAL STOKES ELLIPSOMETERS

(71) Applicant: FemtoMetrix, Inc., Los Angeles, CA (US)

(72) Inventor: Ken James, Morgan Hill, CA (US)

(21) Appl. No.: 18/884,050

(22) Filed: Sep. 12, 2024

Related U.S. Application Data
(60) Provisional application No. 63/582,776, filed on Sep. 14, 2023.

(51) Int. Cl. G01N 21/21; G01N 21/23; G02F 1/37; H01L 21/66

(52) U.S. Cl. CPC G01N 21/211; G01N 21/23; G02F 1/37; G01N 2021/213; G01N 2201/06113; G01N 2201/067; H01L 22/12

(57) ABSTRACT

Described herein are methods and systems for measuring polarization states of nonlinearly generated light by a sample illuminated in response to receiving an incident beam having a known polarization state to determine a characteristic of the sample. The system includes an optical ellipsometer configured to be included in-line of a semiconductor fabrication line and generate measured signals proportional to different polarization parameters of second-harmonic light nonlinearly generated light by the sample, allowing determination of a complete polarization state of the second harmonic light using a characteristic of the sample is determined.

### INCORPORATION BY REFERENCE TO ANY PRIORITY APPLICATIONS

This application claims benefit under 35 U.S.C. § 119(e) of U.S. Provisional Application No. 63/582,776, entitled “NONLINEAR OPTICAL STOKES ELLIPSOMETERS”, filed on Sep. 14, 2023, which is hereby incorporated herein by reference in its entirety.

### BACKGROUND

### Field of Disclosure

Embodiments of the subject matter described herein are related generally to optical metrology, and more particularly to optical metrology using ellipsometric or polarimetric analysis of light produced through Second Harmonic Generation or SHG.

### Description of the Related Art

In the semiconductor industry, chip makers use optical metrology equipment to provide fast, non-contact and nondestructive, evaluation of wafer process steps during processing. Ellipsometry is one of the methods used for evaluation of planar thin film, thick film, multi-layer films, and critical dimensions of three-dimensional (3D) devices.

Linear ellipsometry methods project polarized, broadband incoherent (spectroscopic ellipsometry or SE) or continuous wave (CW) laser light (single wavelength ellipsometry or SWE) onto the sample under test. Various linear ellipsometric methods rely on the continuous, mechanical rotation of polarizing or phase retarding optics to generate the incident polarization states and perform the analysis. The scattered light is analyzed for polarization differences relative to the incident beam which were imparted by the sample. These differences are registered by a detector as variable intensities after passing a final analyzing-polarizer or waveplate-polarizer combination. This is repeated for many incident polarizations. The aim of the various ellipsometers is to directly or indirectly resolve the 4×4 sample Mueller Matrix which describes the spatial dependence of refractive index within the sample and determines the intensive polarizing properties of the sample. This data can be fitted to an optical model of the combined sample-ellipsometer system. Model parameters may be selectively constrained or floated to optimize fitting and yield up the extensive sample properties like thickness and critical dimensions.

### BRIEF DESCRIPTION OF THE DRAWINGS

FIG. 1 schematically illustrates an optical metrology device or a polarization-based sample characterization system configured to characterize a non-linear optical response of the sample by measuring polarization states of a portion of sample beam nonlinearly generated by illuminating a target region of the sample by an incident beam having specified polarization states.

FIG. 2 is a flow diagram illustrating an example process that may be performed by or using the system shown in FIG. 1 to determine optical properties of the target region of the sample.

FIG. 3 schematically illustrates an example implementation of the system shown in FIG. 1 that analyzes nonlinearly generated light using four separate photodetectors and bulk optical retarders and polarizers.

FIG. 4A schematically illustrates an example implementation of the system shown in FIG. 1 that analyzes nonlinearly generated light using a spatial light modulator (SLM) and a polarization sensing camera (PSC).

FIG. 4B illustrates an example arrangement and alignment of the retarder elements of the SLM, the polarizer elements of the PSC, and photodetector elements of the PSC.

FIG. 5A schematically illustrates an example implementation of the system shown in FIG. 4A that uses a vortex optical beam to interrogate the sample.

FIG. 5B schematically illustrates an example implementation of the system shown in FIG. 5A that uses an SLM to generate and control a vortex optical beam to interrogate the sample.

FIG. 6 schematically illustrates an example implementation of the system shown in FIG. 5B that may be configured during a calibration period to allow for correcting (e.g., reducing) a wave-front distortion along the optical path of the incident optical beam.

FIG. 7A schematically illustrates a side cross-sectional view of a sample comprising an interface between an oxide layer and a silicon substrate interrogated by incident light that interacts with interfaces therein.

FIG. 7B schematically illustrates positioning of an AFM tip and a corona gun head with respect to a target region on the top major surface of a sample for controlling and measuring surface charge over the sample during optical interrogation by an incident optical beam.

### DETAILED DESCRIPTION

Various linear ellipsometric methods rely on the continuous, mechanical rotation of polarizing or phase retarding optics to generate the incident polarization states and perform the analyses. In some cases, the absolute positions of the rotating elements are uncertain or unknown at any time except in the instant the motor index pulses are detected (once per rotation). Challenges in motor speed correction, and clock alignment between motor control, detector, and the various signal processing elements can produce uncertainties in the incident and detected polarizations that degrade precision and accuracy.

The spectral content of the signal is generally spectroscopically indistinguishable from the incident beam in linear ellipsometry, where the polarization response of a sample is determined based on a portion of an incident light beam scattered by the sample. As such, any background light or light scattered from optics, when detected, may constitute a significant source of error or noise which can degrade the accuracy and precision of measurements.

Additionally, the time required to physically move the appropriate optical elements through a complete cycle of the polarization states (generally 22.5 or 11.25 degrees per acquisition) used for analysis, may limit the speed at which that linear ellipsometry may produce a complete measurement. In some examples, fitting data to complex models slows the process further (e.g., total acquisition and calculation time of 1-20 seconds/measurement). Efforts to reduce noise and reduce or eliminate other uncertainties may involve averaging multiple scans which slows the acquisition even further.

The development of nonlinear optical Stokes ellipsometry (NOSE) can address some of these problems by relying on the nonlinear optical Second Harmonic Generation (SHG), and a polarimetric architecture that leverages the specificity and speed of SHG to be accurate, precise, and fast.

SHG has been long used as a characterization method for surfaces, interfaces, bulk crystalline or polycrystalline materials, and oriented thin films. The wave mixing process responsible for SHG generates a signal of coherent, polarized light. Polarimetric analysis of the signal can reveal the orientation and magnitude of electric fields that result from interfaces, discontinuities in material composition, fields that are intrinsic to the molecular or granular structure of the material, and those due to strain/shear forces within materials. These in turn may be interpreted to reveal the detailed molecular and surface properties of the materials under study.

The NOSE method may rely on a femtosecond pulsed laser as the fundamental light source. Interaction between the incident, optical electric field (e.g., optical field of light beam on the sample) and those present within the sample (e.g., electric dipoles within the sample) may produce light (second harmonic light) with twice the optical frequency of the fundamental or equivalently half the fundamental wavelength (wavelength of the incident beam). This condition results in a high degree of spectral specificity. The signal (e.g., the second harmonic signal) can be easily distinguishable from all other light sources and is optically (spectrally) filtered to prevent background and systematic sources of light from being detected as signal.

In some cases, a laser pulse repetition rate of 1-100 MHz may be selected to allow a rapid cycle photoelastic modulator (PEM set to 1-100 kHz), to produce enough polarized pulses to step the polarization state hundredths to tenths of a degree per PMT output pulse. This is a very high polarization resolution compared to the single degree to tens of degrees typical of linear ellipsometry. The total acquisition time with full polarization analysis can be completed in tens of microseconds to tens of milliseconds depending on the signal-to-noise ratio for the application. This compares very favorably to the hundreds of milliseconds to tens of seconds for the minimum acquisition times of linear ellipsometry.

NOSE has been overlooked as a technique for characterizing electronic microcircuits, including integrated circuits on silicon wafers. The methods, systems, designs and configurations described below apply NOSE to the characterization of integrated circuits, including metrology, defect detection, band structure engineering, etc.

Spectroscopic Ellipsometry (SE) is conventionally used as a method for thin film (TF) and optical critical dimension (OCD) metrology for Semiconductor High-Volume Manufacturing (HVM).

SE can determine the complex valued elements of the Jones and/or Mueller matrices which describe aspects of a sample's optical and electronic properties.

SE may include illuminating the sample with continuously-rotating-polarizations of broadband light. The polarization states of the reflected light may be analyzed with various combinations of fixed and rotating retarders and polarizers converting them to relative intensities that vary in time. Next, the wavelength dependence of the signal can be analyzed in a spectrometer, capturing it as time dependent spectral distributions of intensities.

The electro-mechanical rotation control, synchronization, and the relative motor speeds, however, can impose limitations on production and analysis of polarization states. For example, rotation asymmetries, detector acquisition triggering, acquisition cycle duration and max acquisition frequency, individually or in combination, can produce unwanted harmonics, cycle jitter and signal smearing. As such, in some cases, the measurements are averaged over even number multiples of the acquisition cycle and the resulting signals are described by a minimum set (8,16 or 32) of minimally sampled polarization states (<every 5.625°) and long move-acquire-measurement (MAM) times.

In some cases, the data are fitted to optical models which are optimized to give sample film thickness, refractive index and critical dimension values.

The SE method is generally considered to be a non-destructive, sensitive and relatively fast (e.g., OCD MAM of 1-2 sec where OCD refers to optical critical dimension) compared, for example, to SEM/TEM, XRD, XRF, and XPS.

Conventional SE devices that depend on electro-mechanical control may be nearing the limits of feasible improvement. This may prevent significant strides forward in development for increased speed and emerging applications. Constructing ellipsometers that can resolve all elements of the sample Mueller Matrix can be useful.

In ellipsometry, p- and s-polarized light waves are irradiated onto a sample at or near the Brewster angle. The reflection of incident light and/or its interaction with the sample can be modeled by an incident Jones vector operating on the sample Jones matrix (real components of polarization) and calculating the expected output Jones vector. Some methods use incident Stokes vectors operating on the sample Mueller matrix (real and complex polarization) to predict the output Stokes vector. In some cases, the sample Mueller matrix may be determined from the changes to the measured output Stokes vector from the known input Stokes vector.

In some cases, Mueller elements quantifying absorption, linear and circular dichroism and birefringence can be derived by fitting data to accurate optical models, and this in turn allows a degree of dimensional analysis of modeled structures.

Example features of various disclosed NOSE methods and systems In various embodiments of NOSE, the Stokes vector determined for nonlinearly generated light together with information about the polarization state of the incident light permits calculation of the Mueller matrix. The Mueller Matrix completely describes the optical nature of a material and is the current basis for the industry standard optical thin film and Optical Critical Dimension (OCD) metrology methods. So NOSE may provide a faster alternate method for classic thin film and OCD metrology, but the nonlinear sensitivity offers specificity that is difficult for standard ellipsometry physically to achieve. In some cases, NOSE may allow direct measurement of the components of the susceptibility tensor which contains the Stokes vector components. Various designs and methods described herein may potentially (although not necessarily) include one or more features listed below.
The measurements are based on nonlinear atomic/molecular interactions: Second Harmonic (SHG), for example, may directly encode the fundamental nature of materials together with the influences of the local environment, which together may be responsible for the optical/electrical behavior of the sample under test.
Using electrically tunable optical retarder (e.g., an electro-optic or photoelectric modulator), the sample is exposed to a large and customizable continuum of polarization states rapidly and incrementally, without moving any component or relying on movement of any physical component to provide for variation in the polarization states.
The measurement may be taken at high repetition rate and/or using transform-limited laser pulses.
The electrically tunable optical retarder, allows fast and discrete control of incident polarization state.
In some implementations, one full-cycle scan (e.g., from 0 degree to 180 degrees, sampled every 0.1125 degrees, using 1,600 pulses per polarization state) can be completed in 20 μs or less.
Simultaneous detection of at least three different beams or at least three different portions of a beam extracted from the nonlinearly generated light from the sample for different polarization states of the light incident on the sample. Each of the at least three different beams or at least three different portions have different polarization states.
Complete characterization of the polarization state of the nonlinearly generated light received from the sample for different polarization state of the light incident on the sample (e.g., using the three different beams or beam portions referenced in the bullet above).
Analytical method which resolves the complete Nonlinear Susceptibility Tensor (χ⁽²⁾) and by extension the Jones and Mueller Matrices in 20 μs-12.5 ms.
Simultaneous sample exposure to an on-the-fly-customizable continuum of polarization states in a repeating pattern around the incident beam profile (e.g., using a vortex optical beam).
Simultaneous, 2D, and complete sample characterization at each incident polarization state.
Analytical method which resolves the complete Nonlinear Susceptibility Tensor in 2D (2D χ⁽²⁾) and by extension the 2D Jones and Mueller Matrices in ˜7 ms.
New physics in Semiconductor Metrology; Highly Differentiated
Physics of nonlinear optical interactions may be used to derive the susceptibility tensor of the sample and a full Mueller Matrix.
High Speed Acquisition (χ⁽²⁾ in 20 μs-12.5 ms)
Simultaneous exposure of at least three detectors to nonlinearly generated light received from the sample resulting in at least three detector signals indicative of the Stokes parameters or from which the Stokes parameters can be derived. Complete polarization analysis that is a Complete polarization analysis can comprise passive data collection. The data collection may be performed without moving or physically adjusting any optical components.
Using second harmonic generation (SHG) can provide high Specificity.
High Sensitivity: analyzing polarization of SHG instead of the fundamental wavelength may allow high sensitivity detection of certain features and defects. SHG is a direct and proportional vector response to electric fields present within the material under test. These electric fields are physically responsible for the electronic character and function of microelectronic devices and include effects of both the design and unwanted manufacturing defects. These can be specifically probed with SHG while other metrology methods gather indirect or inferential electronic information from measurements of optical properties of device structures.
High polarization resolution
Oversampled at maximum acquisition speed: NOSE method permits breaking up the polarization sample space into arbitrarily small segments at little or no cost to the duration or stability of the minimum complete sample set.
Requires no moving parts (e.g., to cycle through a plurality of polarization states for the input light and/or to capture light at three or more detectors to determine the polarization state of the light output from the sample).
Using vortex optical beams, the polarization states for characterizing the sample can be simultaneously generated.
Two-dimensional (2D) profile of Stokes vectors (e.g., determined based on a polarization profile of a vortex optical beam) may be used to determine sample's Mueller Matrix by simultaneous, passive analysis and detection.

### Experimental Arrangement for NOSE

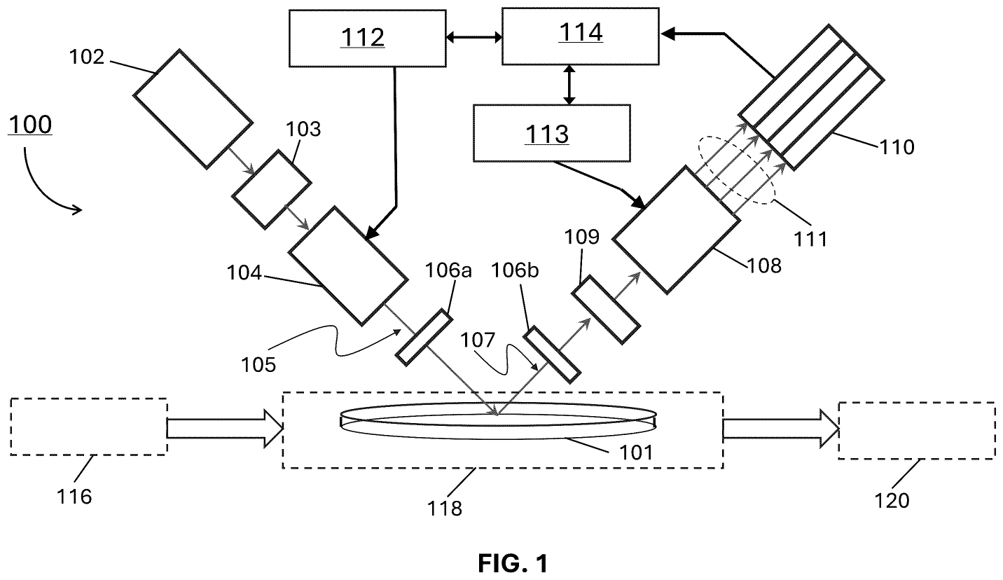

FIG. 1 schematically illustrates an optical metrology device or polarization-based sample characterization system 100, herein referred to as the “system”, configured to illuminate a target region of the sample 101 with an incident light beam 105 having a specified polarization state, and determine the polarization state of at least a portion of the sample light beam 107 generated as a result of a nonlinear optical interaction of the incident light beam 105 with the sample 101. The nonlinearly generated portion of sample light beam 105 may be analyzed for polarization differences relative to the incident light beam which were imparted by sample 101. In some implementations, the polarization differences may be registered as variable intensities. In some examples, the sample 101 may be moved with respect to the incident beam 105 to interrogate different regions of the sample 101 with the incident beam 105. For example, the sample 101 may be mounted on a scanner or an adjustable stage that moves the sample 101, for example, in orthogonal directions within a plane substantially parallel to a major surface of the sample 101. Alternately or additionally, the input beam may be scanned with respect to the sample 101. In some embodiments, the sample 101 may comprise a semiconductor wafer having an integrated circuit thereon.

In some embodiments, the system 100 may comprise an ellipsometer such as a nonlinear optical Stokes ellipsometer (NOSE) configured to be included in-line of a semiconductor fabrication line (e.g., semiconductor integrated circuit fabrication line) to determine a characteristic of the sample 101. For example, a sample wafer 101 may be transferred from a characterization or fabrication stage or station of a fabrication line to a characterization or measurement station or stage of the fabrication line comprising the system 100, and then transferred from the characterization or measurement stage or station comprising the system to another stage or station that can be another characterization or measurement stage/station or another fabrication stage/station of the fabrication line. (In some cases, the sample wafer 101 may be transferred from the characterization or measurement station or stage 118 back to the previous characterization or fabrication stage or station 116 of a fabrication line.) Such transfers may be done, for example, by a human or via automation, e.g., by a robotic arm. Such measurements and/or characterization may thus be performed within the same facility. Moreover, the time for transferring the sample wafer 101 to the measurement or characterization stage or station and for completing the measurement, may be sufficiently short such that the measurement or characterization does not interfere with the operation and/or degrade the performance of the fabrication line. Likewise, measurements can be performed on semiconductor wafers (e.g., sample 101) having integrated circuits thereon and/or that are in the process of having integrated circuits fabricated thereon.

In some examples, the sample light beam 105 may comprise the second harmonic of an incident light beam and the system 100 may perform ellipsometric or polarimetric analysis of light produced through Second Harmonic Generation or SHG to determine characteristics of the sample 101.

In some embodiments, the system 100 may be configured to generate signals that can provide information for determining the Stokes vectors of the sample light beam 107 (e.g., the nonlinearly generated portion of the sample light beam). In some examples, the system 100 can generate signals that provide information for determining four Stokes parameters, S0, S1, S2, S3 of the sample light beam 107. In some embodiments, the system 100 may be configured to generate signals that can provide information for determining four polarization parameters for determining a polarization state (e.g., a complete polarization state) for the sample light beam 107. In some such embodiments, the four polarization parameters may be used to determine four Stokes parameters, S0, S1, S2, S3 of the sample light beam 107. In some such embodiments, the four polarization parameters may comprise four optical intensities associated with different wave front portions of the sample beam 107. In some embodiments, the system 100 may be configured to generate signals that can provide information for determining three polarization parameters for determining a polarization state (e.g., a complete polarization state) for the sample light beam 107. In some such embodiments, the three polarization parameters may be used to determine four Stokes parameters, S0, S1, S2, S3 of the sample light beam 107. In some such embodiments, the three polarization parameters may comprise three optical intensities associated with different portions of the light output by the sample or with different wavefront portions of the sample beam 107.

In some embodiments, the system 100 may cycle the polarization of the incident beam 105 through a sequence of polarization states and generate signals that provide information for determining Stokes vectors for different polarization states of the incident beam. In some embodiments, a computing system (e.g., a computing system of the system 100, which may possibly comprises a processor) may be configured to derive a nonlinear susceptibility tensor for the sample 101 using the measured Stokes vectors of the nonlinearly generated portion of sample beam/light 107 and the respective Stokes vectors for the incident beam 105 corresponding to the polarization states in the sequence of the polarization states). In some embodiments, the computing system may derive a measured Mueller Matrix for the sample 101 (e.g., for a target region of the sample illuminated by the incident beam 105), using the measured Stokes vectors of the nonlinearly generated portion of sample beam/light 107 and the respective Stokes vectors for the incident beam 105. Separately, the computing system may determine a parameterized Mueller Matrix (e.g., a Mueller Matrix that partially includes one or more known values as well as partially includes one or more unknown values or variables) based on a parametrized susceptibility tensor (e.g., a susceptibility tensor that partially includes one or more known values as well as partially includes one or more unknown values or variables) generated based on composition and/or geometrical characteristics of sample 101 and estimate the unknown parameter the parameterized Mueller Matrix with the measured Mueller Matrix. In some examples, the data from the measured Mueller Matrix may be fitted to parameterized Mueller Matrix. In some examples, the unknown parameters may be selectively constrained or floated to facilitate fitting and yield up the extensive sample properties like film thickness, layer structure, interfaces, and critical dimensions.

In some embodiments, the sample 101 may comprise a semiconductor material. In some embodiments, the sample 101 may comprise a semiconductor wafer and/or substrate. In some examples, a top main surface of the sample 101 may comprise one or more electronic devices, integrated circuits, and/or microfabricated structures or partially fabricated electronic devices, integrated circuits and/or structures as the wafer may be in a process for fabricating such devices and/or structures. In some embodiments, the nonlinear optical interaction may comprise a second order nonlinear optical interaction. The sample light beam/light 107 may comprise, for example, a second harmonic optical frequency with respect to the optical frequency of the incident light beam 105.

As illustrated, the system 100 may comprise a light source 102 that generates a light beam. In various implementations, the system 100 further comprises polarization optics 104 that sets the polarization of the light. The polarization optics may comprise, for example, a polarization state generator that receives input light and outputs different polarization states depending on the setting of the polarization state generator. In some cases, the polarization state generator may output light having a time varying polarization state. The polarization state generator can thus produce a plurality of different polarization states, that are shown in the example design depicted in FIG. 1 as being incident on the sample. In the design of FIG. 1, for example, the polarization state generator receives an initial polarized light beam and generates the incident beam 105 having a plurality of different polarization states that change with time. FIG. 1 further shows input optics 106a configured to focus the incident beam 105 onto the sample 101. In some designs, the system 100 further comprises beam conditioning optics 103 that may be configured to alter the light output from the light source 102 prior to being received by the polarization optics or polarization state generator 104. The beam conditioning optics 103 may comprise, for example, one or more retarders or polarizers to provide the light input into the polarization optics, e.g., the polarization state generator 104, with the appropriate or suitable polarization state. The light source 102 may for example output linearly polarized light. The beam conditioning optical may comprise, for example, a retarder to rotate the linearly polarized light to a suitable orientation prior to being input into the polarization state generator 104. In some implementation, the beam conditioning optics 103 may comprise a polarizer to provide a suitable polarization state to the light received by the polarization state generator 104. The beam conditioning optics 103 thus may comprise one or more retarders and/or polarizers or other optical elements configured to alter the polarization state of the light. The beam conditioning optics 103 may additionally or alternatively comprise one or more lenses, optical filters, or other types of optical elements.

In some examples, the polarization state generator 104 may not include any moving parts. In some cases, the polarization state of the incident beam 105 may be adjusted, tailored, or varied without moving (e.g., rotating) any optical component along the optical path of the incident light beam 105, which may increase the speed of the system 100 and reduce the data acquisition time

The polarization state generator 104 may comprise, for example, a retarder configured to vary the phase difference introduced in orthogonal polarization components (e.g., s and p polarization components with respect to the surface of the sample 101) of the light beam received from the beam conditioning optics (e.g. initial polarizer) 103 when passing through the retarder. In some cases, the retarder of the polarization state generator may be configured to be varied via photoelastic effect, or an electro-optic effect. Advantageously, using such optical effects for controlling retardation along two orthogonal polarization components allows controlling, modulating, varying, and/or adjusting the polarization state of the incident beam 105 without using a moving part or relying on moving parts to produce such changes in polarization state. In various implementations, phase differences introduced between orthogonal polarization components by the polarization state generator 104 can be from 0 to 45 degrees, from 45 degrees to 90 degrees, from 90 degrees, to 135 degrees, from 135 degrees to 180 degrees, or any ranges formed by the values or other ranges larger or smaller.

In various implementations, the polarization state generator 104 may comprise a photoelastic modulator, an electro-optic modulator, a liquid crystal modulator or any combination thereof. In some cases, the polarization state generator 104 may comprise a spatial light modulator (SLM), e.g., a spatial light modulator formed by a plurality of a liquid crystal modulating elements (or pixels), for example, in an array.

Advantageously, using an SLM as the polarization state generator may allow generation of vortex optical beams having different polarization states, and the controllably adjusting the characteristics of the vortex optical beam.

In some implementations, at least two different wavefront portions of the incident beam 105 may comprise different polarization states. For example, the polarization state generator 104 individually or combined with another optical component (e.g., disposed between the polarization state generator 104 and the input optics 106a), may be configured to convert a light beam received from the beam conditioning optics (e.g., initial polarizer) 103 into a vortex optical beam comprising different polarization states distributed over a wavefront of the vortex optical beam or over a cross-section such as transverse plane perpendicular to the direction of propagation of the vortex beam (the incident beam 105).

In some implementations, the time varying polarization state of the incident light beam 105 may vary periodically with a polarization variation period. For example, during one polarization variation period, the polarization state generator 104 may be configured to change the polarization state of the incident optical beam 105 from linear s-polarization to a first elliptical polarization, to a circular polarization, to a second elliptical polarization, and to linear p-polarization. In some examples, the polarization state of the incident light beam may change between a plurality of discrete polarization states in a stepwise manner. In some examples, at least during a portion of a polarization variation period, the polarization state of the input or incident beam 105 may change continuously.

In some embodiments, the polarization state generator 104 may be configured to cycle the polarization state of the incident beam through a plurality of elliptical polarization states, a plurality of linear and elliptical polarization states, a plurality of linear, elliptical, and circular polarization states, etc.

In some embodiments, the polarization state generator 104 may be configured to cycle through different phase differences between orthogonal polarization components (e.g., s and p polarization components with respect to the surface of the sample 101).

In some implementations, the polarization state generator 104 may control the polarization state of the incident beam 105 based on a first control signal received from a first electronic control circuit or control electronics 112. In some implementations, the first electronic control circuit or control electronics 112 may be configured to generate the first control signal based on a user input and/or or data received from a computing system 114 or otherwise. For example, the first electronic control circuit or control electronics may comprise hardwired logic that produces a signal for causing the polarization state generator to cycle through phase differences between orthogonal polarization components (e.g., s and p components) to cycle through different polarization states.

In some embodiments, the system 100 may further comprise a plurality of optical retarders 108, configured to receive the light beam produced by the sample beam 107 and generate an optical output 111 comprising a plurality of output beams and/or output wavefront regions, where at least two output beams or two wavefront regions comprise different polarization states with respect to a wavefront or wavefront regions of the sample beam 107. In various embodiments, the plurality of retarders 108 may generate the plurality of output beams and/or wavefront regions simultaneously, sequentially, or a combination thereof. In some cases, the plurality of output beams and/or wavefront regions may comprise different wavefront regions of the sample beam 107. In some examples, the plurality of retarders 108 may split the sample beam 107 generated by the sample 101 into at least two output beams and transmit them via different optical retarders. In some examples, the plurality of retarders 108 may comprise at least two different optical retarders intercepting two different wavefront regions of the sample beam 107 and may be configured to provide different amounts of retardation to the two different wavefront regions, e.g., relative to respective wavefront or wavefront regions of the sample beam 107 received by the plurality of retarders 108.

In some embodiments, the plurality of retarders 108 may comprise a plurality of half-wave or quarter-wave retarders. In some embodiments, the plurality of retarders 108 may comprise a plurality of half-wave and quarter-wave retardances.

In various designs, the plurality of retarders 108 comprises an array of retarders. In some embodiments, the plurality of retarders 108 may comprise a liquid crystal 2D phase array (e.g., a nematic 2D phase array). Accordingly, the plurality of retarders 108 may comprise tunable retarders configured to generate half-wave or quarter-wave retardances, for example, based on one or more electrical signals applied to the tunable retarder (e.g., liquid crystal 2D phase array).

In some examples, the plurality of retarders 108 may comprise a plurality of identical optical retarder groups where an individual optical retarder group comprises at least two different optical retarders (e.g., a half-wave retarder and a quarter-wave retarder). In some examples, an individual optical retarder group may comprise at least two different optical retarders and at least two identical optical retarders. In some examples, an individual optical retarder group may comprise a first and a second pair of identical optical retarders, where the first and second pairs comprise different optical retarders. For example, an individual optical retarder group may comprise two half-wave retarders and two quarter-wave retarders.

In some embodiments, the plurality of retarders 108 may comprise a plurality of adjustable or programmable retarders or retarder elements. In some such embodiments, the optical retardation provided by an adjustable retarder or retarder element may be tuned by a second control signal received from a second electronic control circuit or retardation control electronics 113 configured to generate the second control signal based. This second control signal may be based a user input and/or or data received from the computing system 114 or otherwise. For example, the first electronic control circuit or control electronics may comprise hardwired logic that produces a signal for setting retardance for the different retarders or retarder elements.

In some examples, the second control signal may be configured to adjust the retarder element of the plurality of retarders 108 such that a retarder element of a first retarder group and a respective retarder element of a second retarder group provide substantially the same retardation. In some examples, the second control signal may be configured to adjust the retarder element of the plurality of retarders 108 such that at least two retarder elements of the plurality of retarders 108 (e.g., two retarder elements in a retarder group) provide different retardations (e.g., a half-wave retardation and a quarter-wave retardation).

In some embodiments, plurality of retarders 108 may comprise a spatial light modulator (SLM). As discussed above, the spatial light modulator may comprise a liquid crystal spatial light modulator. The retardance of one or more individual pixels in the spatial light modulator may be adjusted by applying electrical signal(s) thereto.

The system 100 may further comprise a multi-channel optical detection system 110 configured to receive the optical output 111 and generate individual detector signals, e.g., photocurrents or photovoltages, etc., for individual output beams or wavefront regions of the output light 111 received from the plurality of retarders 108. In some cases, an individual channel of the multi-channel optical detection system 110 may receive light from an individual retarder or retarder element of the plurality of retarders 108.

In some implementations, at least two photodetection channels of the multi-channel optical detection system 110 may have different photodetection responses to light having different polarizations. For example, a photodetection channel of the multi-channel optical detection system 110 may generate a first detector signal for light having a first polarization state and a second detector signal different from the first detector signal for light having a second polarization state different from the first polarization state. In some cases, when the first polarization state is a linear polarization, and the second polarization is an elliptical or circular polarization the first and second detector signals can be different at least by 10%.

In some implementations, an individual channel of the multi-channel optical detection system 110 may comprise a polarization analyzer or polarization analyzer (or filter) element, or polarizer or polarizer element and a photodetector or detector or photodetector or detector element configured to receive and detect light transmitted by the polarizer or analyzer element. In some embodiments, the multi-channel optical detection system 110 may comprise an array of polarization analyzers or polarization analyzer elements or polarizers or polarizer elements and a photodetector or detector array (e.g., plurality of sensor pixels) optically aligned with the array of polarization analyzers or polarizers such that a photodetector or detector element of the photodetector or detector array receives light transmitted by a respective polarizer element aligned with the photodetector element. In some such embodiments, an amount of light transmitted to the photodetector element from another polarization analyzer element, which is not optically aligned with the photodetector element, may be smaller than the amount of light received from the respective polarization analyzer element, by a factor larger than or equal to 5, larger than or equal to 10, larger than or equal to 20, larger than or equal to 50, or larger than or equal to 100 or any range formed by any of these values or possible larger or smaller.

In some examples, the photodetector array may comprise a CMOS sensor comprising an array of CMOS pixels. In some cases, a readout system of the CMOS sensor may simultaneously collect, and output detector signals simultaneously generated by the CMOS pixels of the CMOS sensor.

In some examples, the photodetector array may comprise a CCD sensor comprising an array of CCD pixels. In some cases, a readout system of the CCD sensor may collect, and output detector signals generated by the CCD pixels or photodetector elements within a readout period. In some cases, the readout period can be from 1 ms to 5 ms, from 5 ms to 10 ms, from 10 ms to 20 ms, or any ranges formed by these values or larger or smaller. For example, when a CCD sensor includes 1000 pixels, a readout period can be a time interval for collecting and outputting 1000 different sensor signals from the 1000 different pixels. More generally the readout period may be from 1 nanosecond (ns) to 10 ns, from 10 ns to 100 ns, from 100 ns to 1 microsecond (sec), from 1 sec to 10 sec, from 10 sec to 100 sec, from 100 sec to 1 millisecond (ms), from 1 ms to 10 ms, from 10 ms to 20 ms, or any range formed by any of these values or possible larger or smaller depending, for example, on the photodetector array technology.

In some examples, the photodetector array may be sensitive to light having a wavelength from 350-650 nm, from 650 to 750 nm, from 750 nm to 1100 nm, from 1100 nm to 1300 nm from 1300 nm to 1600 or any ranges formed by these values or larger or smaller ranges or different ranges altogether.

Advantageously, simultaneous or fast (e.g., within a readout period of less than 20 ms) collection and output of detector signals usable for measuring multiple (for example three or more) polarization parameters may be self-calibrating and/or self-normalizing. In some cases, e.g., during a calibration period, simultaneous or fast (e.g., within a readout period of less than 20 ms) collection and output of detector signals may allow using a perfect reflector to quantify systematic polarization detection efficiency variations. Additionally, an intensity change that is seen on two detector components at any instant may indicate a systematic intensity or amplifier noise (and won't be considered a polarization related effect).

In some implementations, the polarization differences between the incident beam 105 and the nonlinearly generated portion of the sample beam 107 may be detected using the optical detection system 110 that enables the polarization states to be determined based on variable intensities of the different channels. In some cases, the array of polarization analyzers or polarizers may generate a plurality of wavefront portions or beams having intensities associated with the polarization states of the respective wavefront portions or beams. The photodetector array generates a plurality of detector signals indicative of these polarization states which are components of the polarization state of the light from the sample. Thus, in some examples, the plurality of detector signals may indicate one or more polarization states of second harmonic light received from the sample. In some cases, a groups of detector signals (e.g., a group comprising a plurality of different channels) may indicate polarization states (e.g., complete polarization states) of different wavefront portions of second harmonic light received from sample 101. In some cases, the plurality of detector signals may be used to characterize sample 101.

In some cases, the detector signals may provide information for determining the Stokes vectors of the sample light beam 107 (e.g., the nonlinearly generated portion of the sample light beam). For example, the system 100 can generate signals that provide information for determining four Stokes parameters, S0, S1, S2, S3 of the sample light beam 107. In some embodiments, the detector signals can provide information for determining four polarization parameters for determining a polarization state (e.g., a complete polarization state) for the sample light beam 107. In some such embodiments, the four polarization parameters may be used to determine four Stokes parameters, S0, S1, S2, S3 of the sample light beam 107. In some such embodiments, the four polarization parameters from obtained the four respective detector signals may comprise four intensities associated with different wave front portions of the sample beam 107.

In some embodiments, the multi-channel optical detection system 110 may comprise at least three channels, where an individual channel includes a polarizer element (or retarder element or combination of a polarizer and retarder) different from those of other channels. In some embodiments, the multi-channel optical detection system 110 may comprise at least four channels, where an individual channel includes a polarizer element (or retarder element or combination of a polarizer and retarder) different from those of other channels. In some examples, the polarizer elements of the at least three or at least four different channels may compromise linear polarizers orientated at 0°, 90°, 45°, 135°. In some examples, the polarizer elements of the at least three or the at least four different channels may compromise linear polarizers orientated horizontally, vertically, along first diagonals, along a second diagonal opposite to the first diagonal.

In some embodiments, the light simultaneously incident on each of the at least three or at least four different channels can be proportional to a polarization parameter (e.g., a Stokes parameter) of light received by the multi-channel optical detection system 110. Likewise, in some embodiments, an individual sensor or detector signal produced by the at least three or at least four different channels can be proportional to a polarization parameter (e.g., a Stokes parameter) of light received by the multi-channel optical detection system 110. In some embodiments, three different signals collected by the at least three or at least four different channels, simultaneously or during a single readout period of multi-channel optical detection system 110, can be proportional to three individual polarization parameters (e.g., a Stokes parameters) of light received by the multi-channel optical detection system 110.

In some embodiments, multi-channel optical detection system 110 may comprise multiple groups of channels receiving light from different regions of the target region on the sample 101. In some such embodiments, an individual group of channels may comprise at least three or at least four channels that can produce at least three individual signals proportional to three individual polarization parameters (e.g., a Stokes parameters) of light received by that channel. As such, a plurality of detector signals collected from multiple groups of channels, simultaneously or during a single readout period multi-channel optical detection system 110, may be measured to provide a complete polarization state of nonlinearly generated light received from different portions of the target regions of the sample 101.

In some embodiments, an individual channel may comprise a plurality of photodetector elements or detectors receiving light from the respective polarization element. In some examples, individual channels may comprise the same number of photodetector elements.

In some examples, the detection signals generated by the at least four channels may provide information for determining the Stokes vectors of the nonlinearly generated portion of the sample beam 107.

In some cases, the multi-channel optical detection system 110 may comprise multiple groups of channels, where a group of channels comprise at least four channels, for example, where an individual channel includes polarizer elements comprising linear polarizers orientated horizontally, vertically, along first diagonals, along a second diagonal opposite to the first diagonal. In some cases, two groups of channels may receive nonlinearly generated light substantively from the same region, or the same structural feature. In some such cases, the detector signals generated by the two groups of channels may be used to generate Stokes vectors for the region and the structural feature. For example, respective pairs of detector signals from different ones of the two groups may be used to generate four averaged signals and provide information for generating Stokes vector for the region and the structural feature. In some cases, two groups of channels may receive nonlinearly generated light from two different regions or structural features of the sample 101. In some such cases, the detector signals generated by the two groups of channels may be used to generate Stokes vectors for the two different regions or structural features of sample 101. Although various examples include four or more detectors producing at least four signals for providing four parameters, in various implementations, the system 100 may be configured to generate signals that can provide information for determining three polarization parameters for determining a polarization state (e.g., a complete polarization state) for the sample light beam 107. In some such embodiments, the three polarization parameters may be used to determine four Stokes parameters, S0, S1, S2, S3 of the sample light beam 107. In some such embodiments, the three polarization parameters may comprise three optical intensities associated with different portions of the light output by the sample or with different wavefront portions of the sample beam 107. Accordingly, the system may include three or more detectors for determining three, four or more parameters. The three or more optical detectors may output three or more signals.

In some cases, the incident beam 105 (e.g., a vortex optical beam) may comprise multiple polarization states across the same wavefront or across a cross-section such as a transverse plane perpendicular to the direction of propagation of incident beam 105. In some such cases, the two groups of channels may receive nonlinearly generated light generated by interaction of different wavefront portions of the incident beam 105 with the sample 101. In these cases, the detector signals generated by the two groups of channels may be used to generate Stokes vector for different polarization states of the incident beam. Advantageously, when the incident beam 105 comprises multiple polarization states across the same wavefront, e.g., when the incident beam 105 comprises a vortex optical beam, at least a portion of the measured Muller matrix may be determined by the detector signals generated and/or collected and/or outputted substantially at the same time (e.g., at the same time or within a readout period of less than 20 ms).

In some embodiments, the plurality of detector signals received from the multichannel detection system 110 may be used to generate a polarization map of a target region over the sample 101 illuminated by the incident beam 105.

In some embodiments, the plurality of detector signals received from the multichannel detection system 110 may be used to generate an image of the target region. For example, a computing system may receive the plurality of detector signals and data indicative of a configuration of the plurality of retarders 108, and retrieve image information from the detector signals based at least in part on the configuration of the plurality of retarders 108.

In some embodiments, the multi-channel optical detection system 110 may comprise a polarization sensing camera (also referred to as polarization camera).

In some embodiments, system 100 may comprise input and output optics 106a, 106b, configured to direct the incident light beam 105 on the sample 101 and collect light reflected and/or generated by the sample 101, respectively.

In some embodiments, the system 100 may include a wavelength filter 109 positioned to receive the light 107 from the sample 101 (for example, disposed between the output optics 106b (also referred to as collection optics) and the plurality of retarders 108) to absorb, attenuate, and/or reflect the reflected portion of the incident beam 105 that is not part light produced from the sample as a result of a nonlinear effect. In some examples, the wavelength filter 109 may be configured to transmit nonlinearly generated light (e.g., second harmonic light) having a specified frequency. In some embodiments, the wavelength filter 109 may comprise a short-pass filter to block light having a wavelength greater than 55%, 60%, or 70% of a wavelength of the incident light beam 105 (fundamental wavelength). In some cases, the wavelength filter 109 may comprise a notch or band-pass filter, a tunable birefringent filter, or a stack of different filter types configured to transmit the second harmonic light (SHG wavelength) and block at least the fundamental beam wavelength or may comprise other types of filters.

In some cases, the input optics 106a may comprise one or more lenses (e.g., a microscope objective) configured to receive incident light beam 105 from the polarization state generator 104, alter the wavefront of the incident beam 105 and/or direct the resulting light beam to the sample 101. In some examples, the input optics 106a may alter the wavefront of the incident light beam 105 by focusing the incident light beam 105 on a specified spot or target region on sample 101 (e.g., on a top major surface of sample 101).

The incident beam 105 (e.g., focused incident beam) may interact with the sample 101 via one or more nonlinear optical effects and generate sample beam 107 comprising at least one nonlinearly generated frequency component (e.g., second harmonic of the incident light beam 105). Likewise, in various designs the focused beam has sufficient energy and/or power to induce the nonlinear optical effect in the sample and cause light 107 to be produced from the sample 101 as a result of this nonlinear effect.

In some cases, the output optics 106b may comprise one or more lenses (e.g., an objective lens) configured to collect sample light beam 107 generated and/or reflected by the sample 101, alter the wavefront of the sample light beam 107 and/or direct the resulting sample light beam to the plurality of retarders 108. In some examples, the output optics 106b may alter the wavefront of the sample light beam 107 by collimating the sample light beam 107 and directing the collimated light beam to the plurality of retarders 108.

In some cases, the input optics 106a may be configured to transmit the incident optical beam. For example, a material or an antireflection coating of a lens of input optics 106a may be configured to reduce optical reflection and/or absorption at wavelength near the wavelength of the incident beam 105.

In some cases, the output optics 106b may be configured to transmit a nonlinearly generated portion of the sample beam 107 (e.g., the second harmonic of the optical frequency of the incident beam). For example, a material or an antireflection coating of a lens of the output optics 106b may be configured to reduce optical reflection and/or absorption at wavelength near a second harmonic wavelength substantially equal to 50% of the wavelength of the incident beam 105.

In some embodiments, the system 100 may be configured to characterize a target region of the sample 101 by illuminating the target region by the incident beam 105 having a specified polarization state, determining polarization state of a portion of sample light beam 107 nonlinearly generated as a result of interaction between the incident light beam 105 and sample 101, and comparing the determined polarization state with the specified polarization. In some embodiments, the computing system 114 of the system 100 may be configured to provide a control signal to the polarization state generator 104 via the first electronic control circuit 112 to alter (e.g., to periodically alter) the polarization state of the incident beam 105 according a specified sequence of polarization states and generate a sample beam 107 comprising nonlinearly generated light having modified polarization states with respect to the respective polarization states of the incident beam 105. In some cases, the modified polarization states may carry signatures of the properties of the target region (e.g., information regarding the composition and structural features of the target region). In some examples, in response to receiving a sample beam 107 having a modified polarization state (e.g., with respect to a polarization state from the specified sequence of polarization states), the retardation control circuit or electronics 113 may provide a plurality of individually retarded light beams or wavefront regions to the individual channels of the multi-channel detection system 110. In some implementations, in response to receiving the plurality of individually retarded light beams, the multi-channel detection system 110 may generate a plurality of detector signals and transmit the plurality of detector signals or signals or values based thereon to the computing system 114.

The computing system 114 may, for example, be configured to determine the modified polarization state of the beam 107 and compare the modified polarization state with the respective polarization state of the incident beam 105 to determine an optical response of the target region. In some examples, the optical response may comprise a polarization response represented by a mathematical entity (e.g., a tensor or a matrix). For example, the computing system 114 may be configured to derive a measured Mueller Matrix for the target region on the sample 101 based at least in part on a comparison between the determined modified polarization state of the beam 107 and the respective polarization state of the incident beam 105.

In some embodiments, the computing system 114, or another computing system that receives the determined optical response of the target region (e.g. the measured Mueller Matrix of the target region), may use the determined optical response to determine a property of the target region of the sample. In various implementations, the property of the target region may comprise any one or more of thickness of a layer of the sample 101, material composition of a layer of the sample 101, material composition of the target region, a dimension of a structure formed on the sample 101 (e.g., in a direction parallel, or perpendicular to a major surface of the sample 101), symmetrical properties of a structure formed on the sample 101, periodicity of a structure formed on the sample 101, period of a plurality of layers formed on the sample 101, and the like. The embodiments are not so limited and in various embodiments, other properties of the sample 101 may be extracted or calculated based on the optical response of the target region.

In some embodiments, the system 100 in-line of a semiconductor fabrication line (e.g., a semiconductor integrated circuit fabrication line or process). The system may for example be part of a semiconductor wafer fabrication line for fabricating structures on a semiconductor wafer for example to form integrated circuits thereon. The system can be configured to perform measurements on and/or characterize a material and/or structural property of a sample, e.g., between two fabrication steps, between two measurement steps, or between a fabrication step and a measurement step. For example, the sample wafer 101 may be transferred from a characterization or fabrication stage or station 116 of a fabrication line to a characterization or measurement station or stage 118 of the fabrication line comprising the system 100, and then transferred from the characterization or measurement stage or station 118 to another stage or station 120 that can be another characterization or measurement stage/station or another fabrication stage/station of the fabrication line. (In some cases, the sample wafer 101 may be transferred from the to a characterization or measurement station or stage 118 back to the previous characterization or fabrication stage or station 116 of a fabrication line.) Such transfers may be done, for example, by a human or via automation, e.g., by a robotic arm. Such measurements and/or characterization may thus be performed within the same facility. Moreover, the time for transferring the sample wafer 101 to the measurement or characterization stage or station 118 and for completing the measurement, may be sufficiently short such that the measurement or characterization does not interfere with the operation and/or degrade the performance of the fabrication line. In some cases, the measurement or characterization stage or station 118 may be configured to position, orient and/or align the sample 101 with respect to the system 100 such that a focused incident optical beam provided by the input optics 106a illuminates a target region and/or a structure on the sample 101 and the resulting nonlinearly generated sample beam 107 is collected by the output optics 106.

In some cases, a wavelength (e.g., a center wavelength corresponding to peak power or intensity) of the light source 102 can be from 350 to 500 nm, from 500 nm to 700 nm, from 700 nm to 1000 nm, from 1000 nm to 1550 nm or any ranges formed by these values or larger or smaller. In some cases, the light source 102 may comprise a laser source. In some examples, the laser source may be configured to output a polarized initial beam. In some cases, the laser source may comprise a pulsed laser source. In examples, the pulses of the pulsed laser source may comprise femtosecond pulses. The pulse widths of the pulsed laser source can be from 20 to 100 femtoseconds, 100 to 500 femtoseconds, 500 to 1000 femtoseconds, 1 ns to 5 ns, 5 ns to 10 ns, or any ranges formed by these values or larger or smaller. In some cases, the repetition rate of the pulsed laser source can be from 1 to 10 MHz, from 10 to 50 MHz, from 50 to 100 MHz or any ranges formed by these values or larger or smaller.

In various embodiments, the optical power, energy per pulse for the incident beam 105 may be determined based on a desired laser irradiance (e.g., energy per unit area, per unit time) at the measurement site. The desired laser irradiance may be selected based on the properties of the sample (e.g., scattering properties, spectroscopic absorption, reflection, layers, interfaces, structures formed on the sample, and the like). In some examples, the optical power for the incident beam can be from 100 mW to 300 mw, from 300 mW to 500 mW, from 500 mW to 800 mw, from 800 mW to 1 W or any ranges formed by these values or larger or smaller. In some implementations, the pulse energy of the initial light beam generated by the light source 102 or the incident beam 105 can be from 1 nano-Joules to 100 nano-Joules, from 100 nano-Joules to 500 nano-Joules, from 500 nano-Joules to 1 micro-Joules, from 1-micro-Joules to 100 micro-Joules, from 100 micro-Joules to 500 micro-Joules, from 500 micro-Joules to 1 milli-Joules, from 1 milli-Joules to 30 milli-Joules, from 30 milli-Joules to 50 milli-Joules, or any ranges formed by these values or possibly larger or smaller.

In some examples, the optical power, intensity, or pulse energy of the incident beam 105 may be configured such that the optical power, intensity, or pulse energy of the nonlinearly generated portion of the sample beam 107 (e.g., second harmonic light) is sufficient to generate detector signals having a desired signal-to-noise ratio (e.g., a signal-to-noise ratio larger than 0 dB, 1 dB, 2 dB, 3 dB, 10 dB, 20 dB or any range formed by any of these values or possibly larger). As such in some cases, the optical power, energy per pulse for the incident beam 105 may be determined at least part based on an optical loss in the plurality of retarders 108 and/or a component within the multi-channel detection system 110 through which light is transmitted before being detected by a photodetector or photodetector element that generates a detector signal. In some cases, a upper bound for the pulse energy, intensity, or optical power of the incident beam 105 may be set by a damage threshold of the sample 101.

In some cases, the light source 102 may be configured such that the interaction between the incident light beam 105 and the sample 101 nonlinearly generates light having an optical frequency (e.g., a harmonic frequency) different from an optical frequency (e.g., the fundamental frequency) of the incident beam. For example, a power, a pulse power, a pulse width, an intensity, and/or a wavelength of the light source 102 may be configured such that the incident light beam 105 nonlinearly generates light upon interaction with the sample 101 (e.g., a semiconductor sample).

In some cases, a power, a pulse power, a pulse width, an intensity, and/or a wavelength of the light source 102 may be configured such that the incident light beam 105 generates second harmonic light having sufficient power for generating complete polarization parameters for a desired target region of the sample 101, where second harmonic light comprises light having a center frequency at a second harmonic optical frequency with respect to a center frequency of the incident light beam.

In various implementations, for a polarization state of the input or incident beam 105, generated by the polarization state generator 104, a plurality of nonlinearly generated pulses received (e.g., sequentially received) by the multi-channel detector 110 at different times may generate a plurality of detector signals indicative of complete polarization state of the nonlinearly generated light received from the sample 101. In some cases, the plurality of pulses may comprise 2 to 10 pulses, 10 to 100 pulses, 100 to 1000 pulses, 1000 to 20000 pulses, 20000 to 50000 pulses, 50000 to 10⁵ pulse, 10⁵ to 10⁶ pulses or any ranges formed by these values or larger or smaller value.

In various implementations, for a polarization state of the input or incident beam 105, generated by the polarization state generator 104, a plurality of nonlinearly generated pulses may be received by the multi-channel detector 110 received from different portions of the target region of the sample 101 to generate signals indicative of complete polarization states of the nonlinearly generated light generated by different regions of the sample 101.

In various embodiments, the multi-channel detector 110 (e.g., a readout circuit of the multi-channel detector 110) may sequentially, or simultaneously generate detector signals corresponding to the light received by the plurality of sensors of the multi-channel detector 110, at the same time or substantially at the same time (e.g., within a readout time of from of less than 20 ms).

In some embodiments, the polarization state generator 104 and the plurality of retarders 108 may comprise a spatial light modulator (SLM) comprising for example an array of retarders, e.g., a liquid crystal SLM. In some implementations the plurality of retarders may comprise a photoblastic modulator (PEM), an array photoblastic modulator (PEM) elements (pixels), an electro-optic modulator or an array electro-optic modulator elements (pixels).

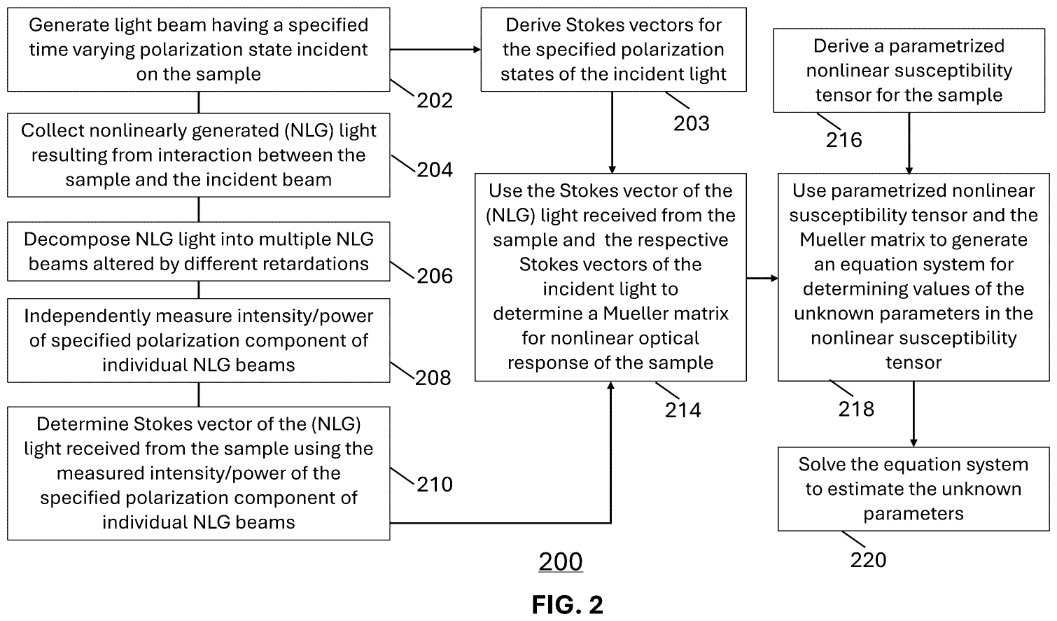

FIG. 2 is a flow diagram illustrating an example process 200 that may be performed by or using the system 100 (e.g., the computing system 114 of the system 100), to determine optical properties of the target region of the sample 101 interrogated by the incident beam 105 and optically characterized by determining a modified polarization state of a nonlinearly generated portion of the sample beam 107 with respect to a respective polarization state of the incident beam 105.

In some embodiments, at least a portion of the process 200 may be performed by an electronic processor (e.g., a processor of the computing system 114) using the first and second electronic circuits 112, 113, and the multi-channel optical detection system 110.

The example process 200 begins at block 202 where the light from the light source 102 provides an initial light beam to the polarization state generator 104 to generate the incident beam 105 having a specified time varying polarization state incident on the sample 101, via the input optics 106a, to generate the sample beam 107 comprising nonlinearly generated (NLG) light (e.g., second harmonic of the incident beam 105).

At block 203, the system 100 may derive Stokes vectors for the time varying polarization state of the incident beam 105. In some examples, each a Stokes vector may be tagged by a stamp indicative of a time of incidence or a pulse number.

At block 204, the sample beam 107 is collected by the output optics 106b and transmitted to through the wavelength filter 109, which removes the reflection of the incident beam 105, to provide the NLG light, resulting from a nonlinear optical interaction (e.g., a second order nonlinear optical interaction) between the sample 101 and the incident beam 105.

At block 206, the system 100 may decompose the NLG light into multiple beams or wavefront regions having different polarization states. In some embodiments, the plurality of retarders 108 may provide different amount of retardation to different regions of a wavefront of light received from the output optics 106b (e.g. a substantially flat wavefront associated with a collimated beam) to alter the respective modified polarizations.

At block 208, the system 100 may independently or separately measure intensity/power of specified polarization components of individual NLG beams or wavefront regions with separate optical detectors (e.g., detector elements of a detector array). In some embodiments, the multi-channel optical detection system 110 may comprise multiple detection channels where an individual channel is configured to measure the optical intensity/power of a polarization component in an individual NLG beam or wavefront region received from the plurality of retarders 108. In some examples, an individual channel of the multi-channel optical detection system 110 may generate a detector signal indicative of the intensity/power of a specified polarization component in an individual NLG beam or wavefront region having a polarization state modified by the sample 101 and altered by the plurality of retarders 108.

At block 210, the system 100 may use the detector signals generated by multi-channel optical detection system 110 to determine a Stokes vector of the (NLG) light received from the sample using the measured intensity/power of the specified polarization component of individual NLG beams.

At block 214, the Stokes vectors of the (NLG) light received from block 210 and the respective a Stokes vectors of the incident light received from block 203, may be used (e.g., by computing system 114 or another computing system) to determine a measured Mueller matrix for nonlinear optical response of the sample 101. In some cases, the stamps (e.g., time or pulse stamps) of the Stokes vectors of the incident beam may be used to match the individual Stokes vectors of the incident beam and the NLG light (nonlinearly generated portion of the sample beam 107).

At block 216, a parameterized nonlinear susceptibility tensor, a partially completed tensor having some values and some unknown variables, may be derived for the sample 101 (e.g., for the target region of the sample), e.g., by computing system 114 or another computing system.

At block 218, the parametrized nonlinear susceptibility tensor derived at block 216 and the measured Mueller matrix determined at block 214 may be used to generate an equation system for determining values of the unknown variables or parameters in the nonlinear susceptibility tensor.

At block 220, the computing system 114 or another computing system may solve the equation system generated at block 218 to estimate the unknown parameters in the nonlinear susceptibility tensor.

As mentioned above, the process shown in the flow diagram of FIG. 2 is an example. Other processes may be used. Likewise, a wide range of variations are possible.

### Example Steps of an Example NOSE Method

A 45° polarized, high repetition rate, femtosecond pulsed, IR laser is used to generate a laser beam (also referred to as fundamental beam).

A high-speed, scanning polarization state generator (Photoelastic Modulator, PEM) is used to produce a stream of pulses whose phase difference between the s- and p-polarization components of different pulses (e.g., each pulse) is constantly cycling between 0 and π and back to 0 again before it is focused onto the sample.

The resulting SHG light may be collected, and the polarization components may be decomposed with retarders and polarizers before registering each components' magnitude (I_{det}^{2ω}) in a photomultiplier tube (PMT) or other optical detector. When properly indexed and assembled, these values provide a complete description of the SHG polarization state in the form of its Stokes vector.

The principles of Nonlinear Optics and the optical symmetries in the instrument and sample are used to describe the Stokes vectors using non-vanishing Nonlinear Susceptibility Tensor elements (χᵢⱼₖ⁽²⁾), hence the complete Susceptibility Tensor and a sample Mueller Matrix, which characterizes the electronic and optical nature of the sample, can be derived.

As mentioned above, these steps are examples. Other steps and other methods may be used. Likewise, a wide range of variations are possible.

NOSE with Four-Detector Polarization Analyzer

In some embodiments, the multichannel detection system 110 may comprise four individual photodetectors (e.g., four photomultipliers), polarizer and retarder optical components, and at least one beam splitter configured to receive the sample beam 107 and redirect a portion of the sample beam 107 to at least one of the photodetectors and transmit the remaining portion to another photodetector to implement the NOSE detection technique for a optically characterizing a sample.

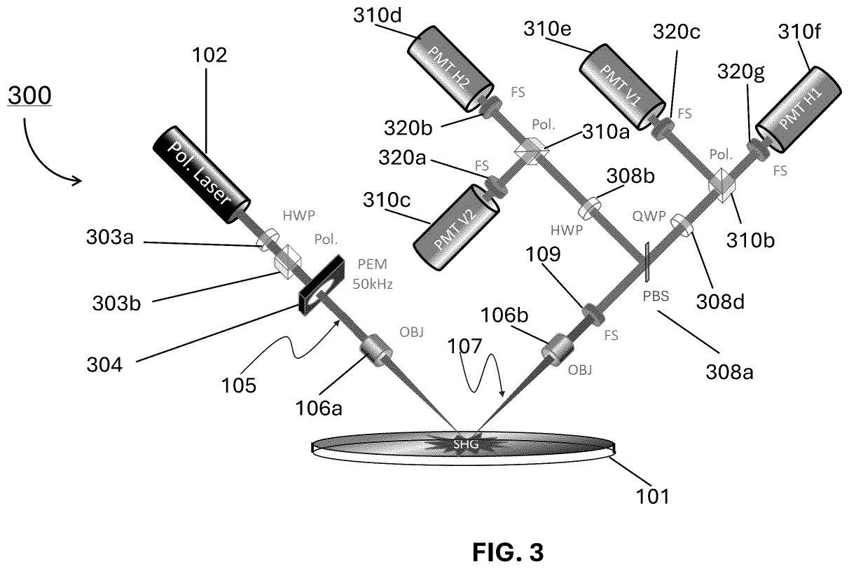

FIG. 3 schematically illustrates a polarization-based sample characterization system 300 configured to characterize a non-linear optical response of the sample 101 by measuring polarization states of a portion of sample beam 107 nonlinearly generated by illuminating a target region of the sample 101 by an incident beam 105 having specified polarization states (e.g., discrete or continuous time-varying polarization states). In some embodiments, the polarization-based sample characterization system 300 may comprise one or more features described above with respect to the polarization-based sample characterization system 100.

In some embodiments, the sample characterization system 300 may comprise a light source 102 that generates an initial light beam, a half-waveplate 303a and a polarizer 303b that may transmit a portion of the initial light beam having a specified polarization to polarization state generator comprising a photoblastic modulator (PEM) 304 that is configured to generate the incident light beam 105 having a time varying polarization state. The incident light beam 105 is transmitted to the input optics 106a that may focus the incident beam 105 on a target region on the sample 101.

In some examples, the half-wave plate 303a and the polarizer 303b may serve as the beam conditioning optics of system 300. In some examples, by rotating the polarizer 303b with respect to the half-waveplate 303a, optical power (or intensity) and polarization state of light transmitted to the photoblastic modulator 304 may be adjusted. The PEM 304 may receive the light transmitted through the polarizer 304 and output the incident beam 105 having a time varying polarization state. In some implementations, the polarization state of the incident beam 105 may vary (e.g., periodically vary) based on a first control signal provided to the PEM 304 (e.g., by an electronic circuit).

In some examples, a wavelength filter disposed to receive light from the PEM 304, may be configured to attenuate, absorb, or reflect a portion of incident light beam 105 and transmit the remaining portion of the input optics 106a. In some examples, the wavelength filter may comprise a long-pass (e.g., visible blocking) filter configured to block light having wavelengths smaller than 55%, 60%, or 70% of a wavelength of the incident light beam 105 (fundamental wavelength). In some cases, the wavelength filter may comprise a notch or band-pass filter, a tunable birefringent filter, or a stack of different filter types configured to transmit the incident light (fundamental wavelength) and block at least the fundamental beam wavelength.

In some embodiments, the system 300 may comprise a beamsplitter 308a, a half-wave plate (HWP) 308b and a quarter-wave plate (QWP) 308d, the later of which are configured to serve the plurality of retarders for the system 300. In some examples, the beamsplitter 308a may be configured to receive the filtered sample beam from the wavelength filter 109, split the filtered sample beam into a first beam or first arm directed to the HWP 308b and a second beam or second arm directed to the QWP 308d. In some cases, the beamsplitter 308a may comprise a polarizing beamsplitter. In some cases, the beamsplitter 308a may comprise a partially polarizing beamsplitter or variable polarizing beamsplitter configured to allow independent control of the horizontal and vertical polarization splitting ratios. In some cases, two or more polarizing components at least one which can be moved, rotated, or otherwise adjusted with respect to the other ones to allow independent control of the horizontal and vertical polarization splitting ratios may be used to split the beam into two arms.

In some embodiments, the system 300 may comprise first and second polarization beamsplitters 310a, 310b, configured to respectively split the first and second beams received from the HWP 308b and QWP 308d into four beams having different polarization states. As shown, the system may further comprise four photodetectors (e.g. four photo multipliers) 310c, 310d, 310e, 310f, configured to receive the beams output by the polarization beam splitters 310a, 310b. In some examples, the combination of the polarization beam splitters 310a, 310b and detectors 310c, 310d, 310e, 310f, may serve as the multichannel optical detection system of system 300.

In some examples, the first polarizing beamsplitter 310a may redirect a first portion of the first beam (received from HWP 308b) having a first polarization state to a first photodetector 310c and a second portion of the first beam, having a second polarization state to a second photodetector 310d. The second polarizing beam splitter 310b may redirect a first portion of the second beam (received from QWP 308d), having a third polarization state to a third photodetector 310e and a second portion of the second beam, having a fourth polarization state to a fourth photodetector 310d. In some embodiments, the first, second, third, and fourth polarization states can be different polarization states. In some examples, the first, second, third, and fourth polarization states can be linear polarization states at 45 degrees, 90 degrees, 135 degrees, and 180 degrees, respectively. In some embodiments, the preponderance of “vertical” and “horizontal” surfaces in opto-mechanical structures may produce physical biases, enhancing the efficiency of production or propagation of “vertical” and “horizontal” polarizations in the system. In some such embodiments, decomposing the sample beam 107 into four beams having different polarizations (e.g., each 45 degrees rotated with respect to the other) may isolate instrumentation optical biases and permit complete analysis, free from or with reduce contribution of such degenerate polarization components. In some embodiments, during a measurement period, the QWP 308d may be rotated to provide different polarization states to the polarizing beamsplitter 310b.

In some embodiments, the system 300 may additionally include wavelength filters 320a, 320b, 320c, 320g, configured to filter portions of the first and second beams directed to the photodetectors. For example, a wavelength filter of wavelength filters 320a, 320b, 320c, 320g, may be positioned to intercept a light beam received from the first or second polarization beam splitters 310a, 310b, and to transmit the filtered light beam to one of the photodetectors 310c-310f. In some examples, the filters 320a, 320b, 320c, 320g, may be configured to further attenuate, absorb, or reflect, the portion of incident beam 105 reflected from sample 101 and to transmit the nonlinearly generated light from the sample.

In one example, the fundamental beam is produced by an 800 nm, ˜20-200 fs, 50-100 MHz, 0-3 W laser. A half-wave plate (HWP) in combination with a laser polarizer set to pass horizontally (h) polarized light relative to the wafer surface, is used to attenuate the beam intensity, and set the output polarization. The polarization state of the incident beam is prepared using a Photo-Elastic Modulator (PEM 1-100 kHz) mounted at +45° relative to the wafer surface normal. A long-pass visible blocking filter was placed after the PEM. A pair of objectives focuses the incident beam onto the sample, collects and collimates the exiting beam from the sample.

The second harmonic (SHG) beam passes through a second filter stack (FS) which blocks the fundamental beam and two photon induced fluorescence. After the FS, the SHG beam passes through a partially polarizing beamsplitter (BS, with a portion being reflected) and onto zero-order QWP mounted in an automated rotation stage, the v- and h-polarized electric fields are separated using a polarizing beam splitter cube set to pass h-polarized light, and the signal is detected using two PMTs, each with a short-pass filter stack (FS). The signals from the PMTs are amplified using fast preamplifiers and collected using time-gated photon counting cards. The portion of the beam reflected from the beam splitter (BS) forms a second detection arm with a zero-order HWP and equivalent detection electronics. The intensity of the SHG beam detected by the PMTs is monitored as a function of the PEM state. The total photon counts obtained for each sweep of the PEM are summed to generate a complete data set. Before data processing, the counts from each detector are corrected for dark counts measured on a blank sample.

NOSE with Spatial Light Modulator (SLM)

In some embodiments, the multichannel detection system 110 of system 100 may comprise a spatial light modulator (SLM) for polarization analysis of second harmonic light generated the sample 101 using a two-dimensional NOSE detection technique.

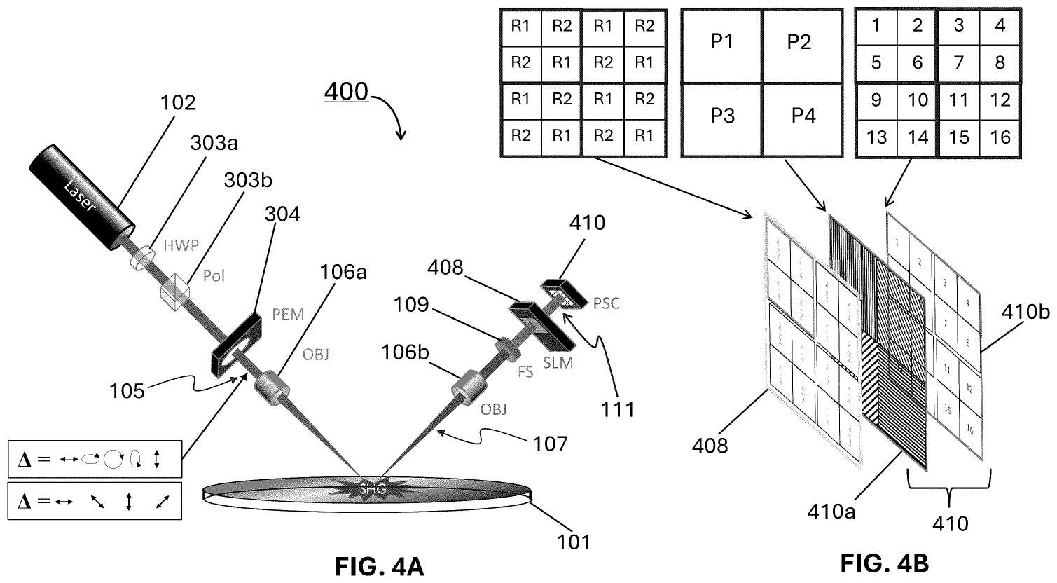

FIG. 4A schematically illustrates another polarization-based sample characterization system 400 configured to characterize a non-linear optical response of a sample 101 by measuring polarization states of a portion of sample beam 107 nonlinearly generated by illuminating a target region of the sample 101 by an incident beam 105 having specified polarization states (e.g., discrete or continuous time-varying polarization states). In some embodiments, the polarization-based sample characterization system 400 may comprise one or more features described above with respect to the polarization-based sample characterization systems 100 and 300.

Similar to the system 300 discussed above, this system 400 may include a light source 102. The system 400 may further include a half-waveplate 303a and a polarizer 303b to vary the intensity of the light from the light source. Moreover, the system 400 may include a PEM 304 to generate an incident light beam 105 having a time varying polarization state and transmit the incident light beam 105 to input optics 106a to focus the incident beam 105 on a target region on the sample 101.

In some embodiments, the system 400 may comprise a spatial light modulator (SLM) 408 serving as the plurality of retarders for the system 300. In particular, in some examples, the SLM 408 may comprise a plurality of controllable retarder elements configured to intercept different wavefront regions of light received from the sample. In the design shown, the light from the sample passes through output optics 106b as well as a wavelength filter 320a. In some embodiments, the plurality of controllable retarder elements may form an array (e.g., a two-dimensional array or matrix) of retarders elements or pixels. In some embodiments, the SLM 408 can be a planar device, and the plurality of controllable retarder elements may be positioned substantially within a single plane. In some examples, the SLM 408 comprises a liquid crystal spatial light modulatory array. This SLM array 408 may comprise a two-dimensional phase array. In some examples, the SLM 408 may comprise a nematic two-dimensional phase array. In some examples, the SLM 408 can include from 1 Megapixels to 5 Megapixels, from 5 Megapixels to 10 Megapixels, from 10 Megapixels to 15 Megapixels, from 515 Megapixels to 20 Megapixels, or any ranges formed by these values or larger or smaller values.

In some examples, the single plane containing the plurality of controllable retarder elements can be substantially orthogonal to a direction of propagation of the light beam (e.g., a collimated light beam) received from the output optics 106b (e.g., via the wavelength filter 109). In some cases, at least a portion of the plurality of retarder elements may have substantially identical dimensions and/or tunability. The retardations of the controllable retarder elements of the SLM 408 may be controlled by a second control signal provided to the SLM 408. In some implementations, the second control signal may comprise a plurality of control signals configured to provide a specified distribution of optical retardation across the SLM 408. In some examples, individual retarder elements (e.g., each retarder element) of the SLM 408 can be individually controlled using a control signal of the plurality of control signals provided to SLM 408. In some implementations, the plurality of control signals may be configured to generate a plurality of retarder groups where a retarder group comprises two or more retarder elements providing different retardations. In some cases, at least two retarder groups include identical number of retarder elements and identical spatial distribution of optical retardation. In some embodiments, the plurality of control signals may be configured to generate at least four identical groups of retarder elements, where an individual group of retarder elements, comprises four regions where at least two regions comprise identical optical retardations. An example of four identical retarder groups is shown in FIG. 4B. In some embodiments (e.g., the example shown in FIG. 4B), the four regions of a group comprise four quadrants of a rectangle or a square such that the immediately adjacent regions comprise different optical retardations (R1, R2 or R2, R1) and the diagonally separated regions comprise identical optical retardations (R1, R1 or R2, R2). As such, the retardation group may comprise two different optical retardation R1 and R2. In some cases, R1 can be a half-wave plate and R2 can be a quarter-wave plate, or vice versa.

In some embodiments, the system 400 may comprise a polarization sensing camera 410 serving as at least part of the multi-channel optical detection system 110 of the system 400. In some cases, e.g., the example shown in FIG. 4B, the polarization sensing camera 410 may comprise a polarization mask 410a and photodetector array 410b. In some examples, the photodetector array 410b may comprise a plurality of detector pixels (e.g., CMOS pixels or CCD pixels). In some cases, the polarization mask 410a may comprise a plurality of polarizers at least two of which are configured to transmit light having different polarization states. In some cases, the polarization mask 410a may comprise at least four polarizers P1, P2, P3, P4 where at least two polarizers are configured to transmit light having different polarization states. In some cases, P1, P2, P3, and P4 can be linear polarizers configured to transmit linearly polarized light having polarization angles or 0, 45, 90, and 135 degrees, respectively (e.g., with respect to P-polarized light).

In some cases, the plurality of polarizers may comprise non-overlapping regions (also referred to as polarization zones) of the polarization mask 410a patterned to increase optical transmission for light having a polarization state specified by the pattern and reduce transmission of other polarization states. In some implementations, at least two polarization zones may have substantially similar shapes and/or substantially equal areas. In some implementations, at least four polarization zones may have substantially similar shapes and/or substantially equal areas. In the example shown in FIG. 4B, the polarization mask 410a comprises four polarization zones having different patterns and thereby configured to transmit light having different polarizations. The four polarization zones of the polarization mask 410a shown in FIG. 4B may have similar shapes (e.g. square or rectangular) and/or areas. In some embodiments, the four polarization zones may form a polarization zone group configured to generate four light beams or four wavefront regions having intensities or optical power indicative of the polarization content of light incident on the polarization zone group with respect to different polarizations of the polarization zone group. Advantageously, in some cases, e.g., when combined with specified optical retardation distribution across an input light beam, such arrangement of the polarization group may allow determining the polarization state of the input light beam by measuring the intensity or optical power of light transmitted by different zones of the zone group. In some examples, measuring the intensity or optical power of light transmitted by through three different zones of a polarization zone group may be proportional to three polarization parameters (Stokes parameters) of the nonlinearly generated light by the sample 101. In some cases, a fourth polarization parameter (Stokes parameter) can be determined from the three polarization parameters, e.g., by adding the three polarization parameters together.

In some embodiments, the photodetector array 410b may comprise a plurality of photodetector elements (e.g., pixels). In some examples, the photodetector elements can be substantially identical photodetector elements having substantially identical optoelectronic response. The photodetector array 410b may be aligned with the polarization mask 410a such that different optical detector elements in the detector array receive light transmitted through different regions (different polarizers) of the polarization mask 410a. In some embodiments, photodetector array 410b may be configured such that equal number of photodetector elements receive light transmitted from individual, respective polarization zones of the polarization mask 410a. For example, the geometry and the density of the photodetector elements in the photodetector array 410b may be configured such that four photodetector elements (e.g., four identical photodetector elements) receive light transmitted from a single individual polarization zone of the polarization mask 410a.

In some embodiments, the polarization sensing camera 410 may be aligned with respect to the SLM 408 to receive light transmitted by at least a portion of the retarder elements of the SLM 408. As shown in FIG. 4B, in some examples, the polarization mask 410a of the polarization sensing camera 410 may be positioned with respect to the SLM 408 such an individual polarization zone of the polarization mask 410a is aligned with a group of retarder elements of the SLM 408, to receive light transmitted by the retarder elements. For example, individual polarization zones of a polarization zone group may be aligned with individual groups of retarder elements of the SLM 408. In the example shown in FIG. 4B, four identical groups of retarders elements (herein referred to as a set of retarder groups) are optically aligned with four respective polarization zones of a polarization zone group of the polarization mask 410a. In some cases, the set of retarder groups and the respective polarization zones may be configured such that by individually measuring the intensity or optical power of light transmitted via the individual polarization zones, the four Stokes parameters of light incident on the four identical groups of retarders can be determined.

Table 1 includes an example arrangement of the SLM 408, polarization mask 410a, and photodetector array 410b and alignment of the retarder elements, polarizers, and detector pixels, therein. In this example, the SLM 408 includes 16 retarder elements, the polarization mask 410a includes 4 polarizers (polarizers P1-P4), and photodetector array 410b includes 16 CMOS pixels (pixels 1-16). The 16 retarder elements comprise four identical groups of retarder elements, each comprising two half-wave retarders (R1) and two quarter-wave retarders (R2) in diagonal positions where an individual polarizer of the polarization mask 410a receives light from one group of retarder elements and transmits light to four detector pixels of the photodetector array 410b. As shown in Table 1, a pair of detector pixels (e.g., 11+16, 9+14, 1+6, . . . ) receives light transmitted through a half-wave retarder (R1) or a quarter-wave retarder (R2) via a linear polarizer having a polarization direction specified in Table 1. In some embodiments, the sum of a detector signal generated by pixels 1, 2, 5, and 6 can be proportional to a first polarization parameter (e.g., first Stokes parameter or S1), the sum of detector signals generated by pixels 11, 12, 15, and 16 can be proportional to a second polarization parameter (e.g., second Stokes parameter or S2), and the detector signals generated by pixels 2 or 5 can be proportional to a third polarization parameter (e.g., third Stokes parameter or S3). As such, in some cases, two groups of pixels illuminated via two different polarizers (or polarization zones) may generate signals that are proportional to individual polarization parameters (e.g., Stokes parameters) of the nonlinearly generated light by the sample.

TABLE 1

| Retardance | Polarization | CMOS Pixels |
|---|---|---|
| λ/2 | 0°/180° | 11 + 16 |
| | 45°/225° | 9 + 14 |
| | 90°/270° | 1 + 6 |
| | 135°/315° | 3 + 8 |
| λ/4 | 0°/180° | 12 + 15 |
| | 45°/225° | 10 + 13 |
| | 90°/270° | 2 + 5 |
| | 135°/315° | 4 + 7 |

In some embodiments, the output optics 106b may be configured to project the sample light beam 107 received from the sample 101 on the SLM 408 (e.g., via the wavelength filter 109). Given that the wavelength filter 109 can be configured to significantly reduce (e.g., attenuate, absorb, reflect) the reflected portion of the incident beam 105 in the light received from the output optics 106b, the light projected on the SLM may substantially comprise nonlinearly generated light received from the target region on the sample 101 (e.g., a region of the sample illuminated by the incident beam and from which the output optics 106b receives light). In some embodiments, the output optics 106b may project nonlinearly generated light received from different portions of the target region on different regions of the SLM 408. For example, nonlinearly generated light received from a first portion of the target region may be substantially projected on a first set of retarder groups comprising four identical groups of retarder elements shown in FIG. 4B and nonlinearly generated light received from a second portion of the target region may be substantially projected on a second set of retarder groups comprising another four identical groups of retarder elements shown. In some embodiments, the photodetector array 410 may be configured to individually measure the light received from the individual retarder groups of the first set of retarder groups through the respective polarization zones to provide at least four detector signals indicative of the polarization state of the nonlinearly generated light received from the first portion of the target region. In some examples, a computing system may receive the at least four individually measured detector signals and generate a Stokes vector for the nonlinearly generated light received from the first portion of the target region. Similarly, the photodetector array 410 may generate detector signals associated with light received the individual retarder groups of the second set of retarder groups through the respective polarization zones and provide the at least four detector signals to the computing system to determine the Stokes vector for the nonlinearly generated light received from the second portion of the target region.

In various embodiments, a number of detector pixels that receive light from a single polarizer or polarization zone can be from 4 to 8, from 8 to 16, from 16 to 32, from 32 to 64, from 64 to 128 or larger. In some cases, a number of detector pixels that receive light from a single polarizer or polarization zone may be determined based on a desired signal-to-noise ratio, a desired resolution of the measured polarization profile, or other criteria. In various embodiments, a number of detector pixels that receive light transmitted from a single retarder element can be from 1 to 4, from 4 to 8, from 8 to 16, from 16 to 32, from 32 to 64, from 64 to 128 or larger. In some cases, when multiple detector pixels receive light from the same retarder element via the same polarizer or polarization zone, the detector signals generated by here detector pixels may be summed, or average, to generate an averaged signal indicating an amount of light received from the retarder element via the polarizer. Such summing or averaging may potentially reduce effect of noise and/or increase the signal-to-noise ratio.

In some examples, by comparing the Stokes vectors determined for the nonlinearly generated light received from the first and second portions of the target region, with the corresponding Stokes vector of the incident beam 105, the computing system may determine element of one or more Muller matrices representing the nonlinear polarization response of the first and second portions of the target region. In some cases, the computing system may use a parametrized or partial nonlinear susceptibility tensor and the one or more Muller matrices to determine certain unknown parameters in the parameterized or partial nonlinear susceptibility tensor, indicating the material or geometrical properties of the first and second portions of the target region and the structures formed therein.

In some examples, a Stokes vector determined for nonlinearly generated light received from the target region may be matched with a corresponding Stokes vector of the incident beam 105, for example, based at least in part on the first control signal provided to the PEM 304. In some examples, the Stokes vector determined for nonlinearly generated light may be matched with the corresponding Stokes vector of the incident beam 105 based at least in part on a pulse control signal provided to the light source 102. For example, the computing system may use a measurement time at which the detector signals are measured and a first control signal provided to the PEM 304 substantially at the measurement time or a specified delay before the measurement time, to determine the Stokes vector of the incident beam 105 corresponding the Stokes vector determined for nonlinearly generated light based on the measured detector signals.

In some embodiments, a second control signal provided to the SLM 408 may be configured based at least in part on the first control signal provided to the PEM 304.

In some embodiments, the polarization state of a nonlinearly generated portion of the sample beam 107 received from a portion of the target region may be determined based on detector signals generated in response of illuminating the sample region by a plurality of optical pulses. In some cases, the plurality of optical pulses may comprise 10 or 50 pulses, 50 to 100 pulses, 100 to 150 pulses, 150 to 200 pulses, or any ranges formed by these values or larger or smaller values. Using more pulses may potentially reduce the effect of noise and/or increase the signal-to-noise ratio or otherwise improve the measurement.

In some examples, the polarization of the initial light beam generated by the source 102, and the orientations HWP 303a and polarizer 303b may be configured to provide light having a s-polarization with respect to the sample 101 to the polarization state generator, e.g., PEM 304. In some cases, the PEM 304 and/or the first control signal provided to the PEM 304, may be configured to change the polarization state of the incident optical beam 105 from linear s-polarization to a first elliptical polarization, to a circular polarization, to a second elliptical polarization, to linear p-polarization, and back to the linear s-polarization, e.g., during a polarization variation period of the polarization state generator. In some examples, the polarization state of the incident light beam 105 may change between a plurality of discrete polarization states in a stepwise manner. For example, a phase difference between two orthogonal polarization components (e.g., Eₓ, E_{y}) may vary in a stepwise manner. In some examples, at least during a portion of the polarization variation period, the polarization state of the incident light beam 105 may vary continuously from a first polarization to a second polarization state. For example, a phase difference between two orthogonal polarization components (e.g., Eₓ, E_{y}) may vary continuously.

In some embodiments, the detector signals generated by the PSC 410 may be used to generate a second harmonic image of the sample comprising of an intensity map of the second harmonic light generated by the sample 101. In some examples, the SLM 408 may be configured to generate the second harmonic image. For example, in some cases, the SLM 408 may be set such that retarder elements (e.g., pixels) have zero retardation. For example, in some cases, the SLM 408 may be set such that most or possible all the retarder element (e.g., pixels) have the same retardation (e.g., possibly zero retardation). Other variations are possible. In some examples, a computing system (e.g., computing system 114) may be configured to process the detector signals received from the PSC 410 to generate the second harmonic image. In some embodiments, the computing system may be configured to execute a first set of machine-readable instructions during a polarization characterization period to determine complete polarization states of nonlinearly generate light received from the sample 101 and use them, in some cases, to derive at least a portion of a Mueller matrix for the sample. In some such embodiments, the computing system may be configured to execute a second set of machine-readable instructions during a second harmonic imaging period to generate a second harmonic image of the sample. Advantageously, a complete polarization profile combined with a second harmonic image can be used to determine more details with respect to the structural properties, material properties, defects, and other characteristics of a semiconductor sample comprising micro/nano-structured devices and integrated circuits. In some cases, a polarization profile and an intensity may of the second harmonic light may be overlapped to identify and/or characterize defects.

In one example implementation, the fundamental beam is produced by 800 nm, ˜20-200 fs, 50-100 MHz, 0-3 W laser. A half-wave plate (HWP) in combination with a laser polarizer set to pass horizontally (h) polarized light relative to the wafer surface, is used to attenuate the beam intensity, and set the output polarization. The polarization state of the incident beam is prepared using a Photo-Elastic Modulator (PEM 1-100 kHz) mounted at +45° relative to the wafer surface normal. A long-pass visible blocking filter is placed after the PEM. A pair of objectives focuses the incident beam onto the sample, collects and collimates the exiting beam from the sample. The second harmonic (SHG) beam passes through a second filter stack (FS) which blocks the fundamental beam and two photon induced fluorescence. Next, the beam is imaged through a nematic 2D phase array set to half-wave and quarter-wave retardance in an alternating pattern before being captured in a polarization sensing camera (PSC). This produces a 2D beam profile of the stokes vectors for each sweep of the PEM, generating a complete data set. Before data processing, the counts from each detector are corrected for dark counts with no sample present.

Some of the existing ellipsometric techniques sample polarization no finer than every 11.5 degrees over multiple full rotations that may take 1 to 5 seconds to collect enough data to characterize a sample. In some embodiments, the proposed methods and systems (e.g., the system 100, 300, 400 described above with respect to FIGS. 1, 3, and 4A) may allow high resolution polarization state. For example, if the polarization state generator, e.g., PEM, is cycling through 0-180 degrees at a speed of 50 kHz, and the laser generates pulses with 50 MHz repetition rate, a trigger delay can be used to select arbitrary polarizations (e.g., ˜0.1 microseconds/degree). In some implementations, any of the systems described above may allow polarization sampling with less than 1 degree resolution through 180 degrees in tens of milliseconds. By comparison to some of the existing methods this approach allows effectively continuous polarization state scanning with high resolution and accuracy. In various embodiments, number of polarization states provided to sample 101 during a polarization rotation cycle (e.g., from 0 to 180 degrees) can be at least 100, at least 200, at least 300, at least 400, at least 500, at least 1000 or any range formed by any of these values or possibly or larger values.

### NOSE Using Optical Vortex Beams

In some cases, vortex beams may be used to characterize a sample based on SHG. Due to their spiral wavefront, vortex beams inherently possess orbital angular momentum (OAM), with each photon carrying OAM of [symbol] ℏ. The phase of vector beams can be characterized by a phase factor [symbol] , where [symbol] is the topological charge value of OAM and represents the rotating period of phase, θ and is the azimuthal angle. Azimuthal phase is imparted to the wave by azimuthal phase retarders called Q-plates The polarization distribution of vector beams can be described by the Jones matrix [cos(mθ); sin(mθ)], where m is the polarization order and represents the rotating period of polarization.

In some embodiments, the incident beam of a polarization-based sample characterization system may comprise a vortex optical beam having a fixed or time varying polarization state or profile. In some cases, the vortex optical beam may comprise an orbital angular momentum (OAM).

In some embodiments, an optical vortex beam polarization state generator (a Q-plate followed by a half- or quarter-wave, zero-order retarder) that is free of continuously moving parts and converts the femtosecond pulsed, polarized cylindrical laser beam to beam with a customizable, azimuthally varying continuum of polarization states. A pair of objectives focuses the incident beam onto the sample, collects and collimates the exiting beam from the sample. The second harmonic (SHG) beam passes through a filter stack (FS) which blocks the fundamental beam and two photon induced fluorescence. Next, the beam is imaged through a (e.g. 10 Mp) nematic 2D phase array set to half-wave and quarter-wave retardance in an alternating pattern before being captured in a polarization sensing camera. This produces a 2D beam profile of the stokes vectors for each sweep of the PEM, generating a complete data set. Before data processing, the counts from each detector are corrected for dark counts with no sample present.

In some embodiments, the polarization profile of the vortex optical beam may comprise two or more wavefront regions having different polarization states and/or a distribution of polarization states across a wavefront or transverse plane perpendicular to direction of propagation of the beam. In some examples, a vortex beam may comprise a plurality of different polarization states at different azimuthal locations about a cross-section of the vortex beam orthogonal to propagation of the vortex beam. In some embodiments, a distribution of polarization states in an incident vortex optical beam may be configured such that nonlinearly generated light resulting from interaction of the vortex optical beam with a sample carries information indicative of a material composition and/or structure feature of the sample 101. In some cases, the vortex optical beam may have a constant polarization state or profile.

In some cases, the polarization profile of a vortex optical beam may comprise polarization states that upon interacting with sample 101 nonlinearly generate light comprising polarization information (e.g., its Stokes vectors) that may be used to determine at least a portion of a Mueller matrix for the sample 101 and thereby the corresponding portion of the nonlinear susceptibility tensor.

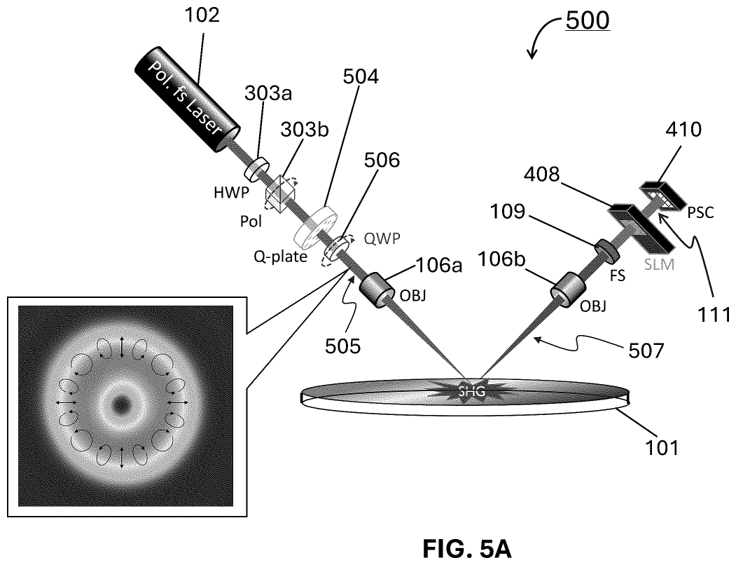

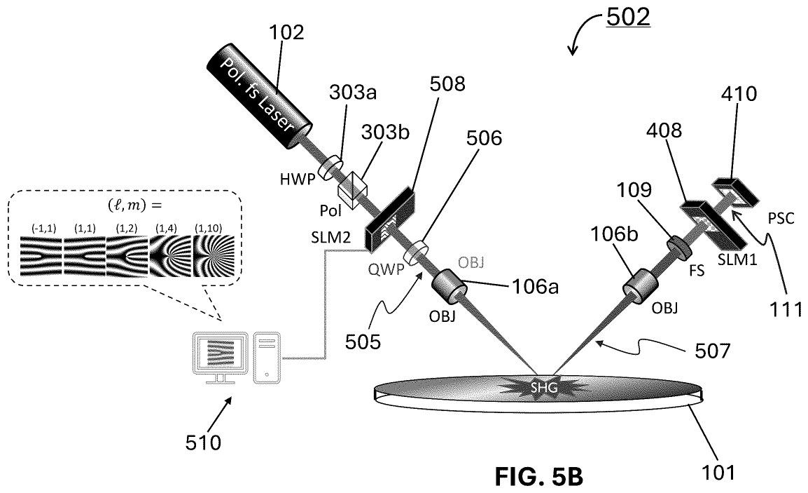

FIG. 5A schematically illustrates a polarization-based sample characterization system 500 configured to characterize a non-linear optical response of a sample 101 by measuring polarization states of a portion of sample beam 507 nonlinearly generated by illuminating a target region of the sample 101 by an incident beam 505 comprising a vortex optical beam. In some embodiments, the polarization-based sample characterization system 500 may comprise one or more features described above with respect to the polarization-based sample characterization systems discussed above (e.g., the system 100, 300, and 400 described above with respect to FIGS. 1, 3, and 4A).

In some embodiments, the system 500 may comprise a Q-plate 504 configured to transform an input optical beam to a vortex optical beam. In some examples, a light source 102 may generate a polarized initial optical beam having a first polarization state (e.g., linear polarization). The system 500 may further comprise a HWP 303a and a polarizer 303b configured to convert or transform the initial optical beam to the input optical beam provided to the Q-plate and having a second polarization state different from the first polarization. The second polarization state can be configured to allow generation of a vortex optical beam using the Q-plate 504. In some cases, the second polarization may comprise a circular polarization. In some cases, the resulting vortex optical beam may comprise multiple polarizations distributed over different wavefront portions of the vortex optical beam. The inset in FIG. 5A illustrates the intensity distribution (e.g., two-dimensional beam profile) for a vortex optical beam, output by the Q-plate 504, across a transverse plane orthogonal to a direction of propagation of the incident beam 505 (the vortex optical beam), indicating a distribution of different polarization states of the optical field at different regions of (e.g., around) the beam profile (herein referred to as a polarization profile).

In some embodiments, the Q-plate 504 may comprise a refractive optical element, a Fresnel-cone, a meta-surface, a permanent liquid crystal, a programable SLM such as a programable liquid crystal SLM array, a programable nematic SLM, etc. In some embodiments, the Q-plate 504 can be an optical element having fixed or time-independent optical properties. In some embodiments, the Q-plate 504 may comprise a tunable optical element whose optical properties may be tuned, adjusted, or modulated, e.g., using one or more electronic signals.

In some cases, the beam profile, orbital angular momentum, polarization state or polarization profile of the vortex beam generated by the Q-plate 504 may be changed or adjusted by rotating the polarizer 303b (e.g., around an axis parallel to the direction of propagation of the input beam).

In some cases, the characteristics (e.g., polarization profile) of the vortex beam generated by the Q-plate 504 may be further adjusted using a QWP 506 positioned to receive the light output from the Q-plate 504. In some cases, instead of QWP 506, a half-wave plate may be used according to the application.

The incident optical beam 505 output from the Q-plate 504 or QWP 506 may be focused on a target region on sample 101 to nonlinearly interact with the sample and potentially generate light having a different frequency compared to the incident beam 505.

The interaction of the incident beam 505 with the sample 101 may generate a sample beam 507 including second-harmonic light comprising polarization states generated by interaction of different wavefront regions of the incident beam 505 having different polarizations with the sample 101.

Output or collection optics 106b and/or an output wavelength filter 109 may received light from the sample such as described above. A plurality of retarders (e.g., an SLM) 408, and a polarization sensing camera 410, may be used to generate detector signals indicative of the polarization states of different wavefront portions of the sample beam 507 (e.g., based on principle described above with respect to the system 400).

In some implementations, the Q-plate (e.g., second SLM) 508 can be an adjustable Q-plate where the optical properties of regions of the Q-plate interacting with the different wavefront regions of the input beam can be independently adjusted to tailor the optical properties of the resulting vortex optical beam. In some implementations, the adjustable Q-plate may be programmed to provide different optical phase shifts to different wavefront regions of a light beam received from the polarizer 303b to form a transmission diffraction grating. In some cases, the diffraction grating may comprise a phase grating. The phase grating may, for example, be formed by a plurality of bands cycling continuously from 0 to π/2 and back to 0, e.g., across the aperture of the adjustable Q-plate. Advantageously, in these implementations, the characteristics of incident beam 505, e.g., with respect to the polarization profile, orbital angular momentum, or beam profile, may be adjusted without rotating polarizer 303b or QWP 506.

In some embodiments, an SLM may be configured to serve as a Q-plate for generating a vortex optical beam. For example, optical path length in different regions (e.g., different pixels) of the SLM may be adjusted to provide a retardation profile across an input beam to convert an input light beam to a vortex optical beam (e.g., by converting spin angular momentum to orbital angular momentum).

FIG. 5B schematically illustrates another polarization-based sample characterization system 502 configured to characterize a non-linear optical response of a sample 101 by measuring polarization states of a portion of sample beam 107 nonlinearly generated by illuminating a target region of the sample 101 with an incident beam 505 comprising a vortex optical beam. The system 502 can be an implementation of the system 500 where the Q-plate comprises a second SLM 508. In some embodiments, the second SLM 508 may comprise a plurality of controllable retardation elements configured, e.g., by a first control signal provided to the second SLM 508, to provide an appropriate retardance distribution to generate the vortex optical beam. In some embodiments, the second SLM 508 may comprise a plurality of controllable transmission elements configured, e.g., by a first control signal provided to the second SLM 508, to generate a diffraction grating or pattern (e.g., comprising a forked pattern) that creates the vortex optical beam. In some implementations, SLM 508 may be programmed to form a transmission diffraction grating to provide different optical phase shifts to different wavefront regions of a light beam received from the polarizer 303b. In some such cases, the diffraction grating may comprise a phase grating. The phase grating may be formed by a plurality of bands cycling (e.g., continuously) from 0 to π/2 and back to 0, e.g., across the aperture of SLM 508. Other designs such as other phase gratings may be employed. In some cases, the polarization state, polarization profile, or other characteristics of the vortex optical beam may be adjusted or modulated by changing the first control signal, which may be provided to the second SLM 508 by a computing system 510 (e.g., via a control circuit). In some cases, the computing system 510 may be programmed to change the polarization profile of the vortex optical beam according to a sequence of specified polarization profiles. Advantageously, using the second SLM 508 as a Q-plate may allow generating an incident beam 505 having an OAM with a specified, adjustable, and/or time varying topological charge value l of OAM and polarization order m. As shown in FIG. 5B the second SLM 508 may be configured by the computing system 510 to generate an incident beam 505 comprising a vortex optical beam having different values of l and m, for example (l, m) can be equal to (−1,1), (1, 1), (1,2), (1, 4), (1,10), or other values.

In some cases, distortions (e.g., wavefront distortions), e.g., along the optical path of the incident beam 505 in systems 500, 502 may cause the resulting vortex optical beam incident on the sample 101 to be different from an intended vortex optical beam corresponding to a specific Q-plate or a pattern programed into the second SLM 508 by the computing system 510. For example, a characteristic (e.g., l, m, an optical field distribution, a polarization profile, or the like) of the vortex optical beam incident on the sample 101 may deviate from an intended or target value, e.g., due to a miss aligned component along the optical path, or a deviation of the optical properties of the initial light beam or a component along the optical path from an expected or assumed optical property based on which a fixed Q-plate is designed, selected, or the second SLM 508 is programed.

In some embodiments, the systems 500, 502, may be calibrated (e.g., prior to sample measurement, between two sample measurement periods, etc.) to make the characteristic of the vortex optical beam incident on the sample 101 closer to the intended or target value, e.g., by correcting the misalignment, or determining modified optical characteristics or parameters of the Q-plate or the second SLM 508, etc., which may result in generation of a desired vortex optical beam in the presence of distortion, which, in some cases, cannot be corrected by optical alignment.

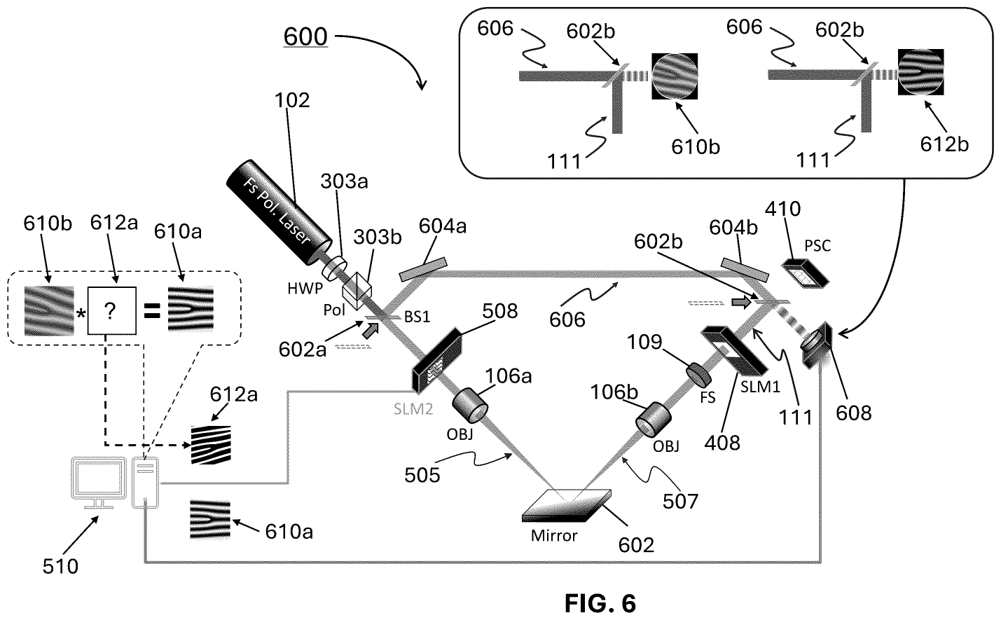

FIG. 6 shows an example system 600 that may be arranged, rearranged, or configured during a calibration period to allow for correcting a wave-front distortion of the optical metrology device (system 600) by moving a mirror or reflector (e.g., planar mirror or reflector) 602 into the metrology device's sample position while moving (e.g., simultaneously moving) a beam splitter 602a and beam combiner 602b into position to route a portion (e.g. 50%) of the beam intensity from just before the Q-plate 504 or the second SLM 508 to and through the beam combiner and into the high-resolution camera (e.g., a CCD or a CMOS camera). The remaining portion (e.g., 50%) of the intensity may continue along the beam path to the mirror 602, through the collection optics (output optics 106b) and to the beam combiner 602b where it is reflected into the high-resolution camera 608, coaxial to the first beam resulting in an interference pattern which is captured by the camera 608.

In some cases, the beamsplitter 602a may be disposed between the light source 102 and/or the polarizer 303b and the Q-plate 504 or the second SLM 508 to intercept the beam transmitted to the Q-plate 504 or the second SLM 508. In some cases, the beam combiner 602b may be disposed between the first SLM 408 and the polarization sensing camera 410 to intercept the light beam 111 transmitted to the polarization sensing camera 410. In various implementations, the beam splitter 602a may be configured to split the light beam received from the light source 102 and/or polarizer 303b into a transmitted beam provided to the Q-plate 504 or SLM 508 and a reference beam 606 rerouted to the beam combiner 602b via two mirrors 604a, 604b. In some examples, the beamsplitter 602a may configured to reroute 5% to 10%, or 10% to 20%, 20% to 30%, 30% to 40%, 40% to 50%, or 50% to 55% of the light beam received from light source 102 and/or the polarizer 303b to the combiner 602b, as the reference beam 606. In some examples, the beam combiner 602b may be configured to transmit at least a portion of the reference beam 606 and reflect at least a portion of the light beam 111 transmitted through the first SLM 408, such that the transmitted portion of the reference beam 606 at least partially overlaps with the reflected portion of the beam 111 to form an interference pattern that can be indicative of an optical field distribution and/or a polarization profile of the incident beam 505. In some examples, the beam combiner 602b may configured to transmit 50% to 60%, 60% to 70%, 70% to 80%, 80% to 90%, or 90% to 100% of reference beam 606 to the camera 608. In some examples, the beam combiner 602b may configured to reflect 5% to 10%, 10% to 20%, 20% to 30%, 30% to 40%, 40% to 50%, 50% to 60%, 60% to 70%, or 70% to 100% of the light beam 111 to the camera 608. In some cases, the beam combiner 602b may be configured such that the intensities of the reflected portion of the light beam 111 and the transmitted portion of the reference beam 606 are substantially equal or different by less than 10%, to form an interference pattern having a highly visible interference fringes. In some cases, the camera 608 may capture the interference pattern and generate a signal (e.g., a video signal) comprising a plurality of intensities proportional to the interference patten. For example, magnitude of different signals can be proportional to optical intensities at different regions of the interference patten 610b.

In some cases, when the second SLM 508 is programed or configured based on an intended pattern 610a, the interference between the reference beam 606 and the reflected portion of the beam 111 may form a first interference pattern 610b that can be different from the intended pattern 610a (e.g., due to distortions). In some examples, a difference between the first interference pattern 610b and intended pattern 610a may be used to calibrate the system 600.

In some embodiments, a feedback circuit (e.g., an electronic circuit, or a computing system) may receive the first interference patten 610b carried by the camera signal, compare the first interference patten 610b with the intended pattern 610a to determine a difference between the first interference patten 610b with the intended pattern 610a, and generate a feedback signal based on the determined difference to modify an optical alignment of an optical component along the optical path of the incident beam 505.

In some embodiments, the computing system 510 (or another computing system) may receive the interference patten 610b carried by the camera signal and process the interference patten 610b to generate a modified pattern 612a for programing the second SLM 508 to generate a vortex optical beam incident on the mirror 602 (or sample 101 during a measurement process) having a desired optical characteristic (e.g., a desired polarization profile).

In some examples, during a calibration process, the second SLM 508 may be programed by an intended pattern 610a (e.g., an intended pattern corresponding to an intended polarization profile of the incident beam 505) to generate a first interference patten 610b. The computing system 510 may use the first interference pattern 610b and the intended pattern 610a, programed into the second SLM 508, to determine the modified pattern 612a such that programing the second SLM 508 with the modified pattern 612a results in generation of a second interference pattern 612b substantially similar or identical to the intended pattern 610a.

In some cases, the convolution of the first interference patten 610b with the modified pattern 612a may result in the intended pattern 610a. As such, in some embodiments, the computing system may determine the modified pattern 612a by deconvolving the first interference patten 610b from the intended pattern 610a.

In some embodiments, after a given sample characterization period or a given number of samples characterized, a user or a computing system may initiate a calibration process by positioning the mirror 602 into the sample position such that the incident beam 505 is reflected by the mirror 602 into the output optics 106b. Additionally, the beam splitter 602a and beam combiner 602b may be brought into position to provide the reference beam 606 and the beam 111 to the camera 608. In some cases, the mirror 602, beamsplitter 602a, and beamcombiner 602b may be automatically positioned by a robotic system, e.g., controlled by the computing system, in response to initiation of the calibration process. During the calibration process, an optical component may be aligned (e.g., by a user or a robotic arm), or a modified pattern 612a may be determined (e.g., by the computing system 510) based on an interference pattern recorded by the camera 608 and an intended pattern 610a stored in the computing system 510 or provided by a user. In some embodiments, the modified pattern 612a may be used to program the second SLM 508 for characterizing samples during a sample characterization period, e.g., immediately after the calibration process.

In some cases, a calibration process may be triggered based on an error or malfunction detected or identified (e.g., by a user or an electronic system) during one or more sample characterization periods. In some cases, error or malfunction may be detected or identified based at least in part on the signals received from polarization sensing camera 410. In some cases, error or malfunction may be detected or identified based at least in part on a sensor signal received from a sensor configured to monitor an intensity or optical power, a polarization, scattered light, or another optical parameter along the optical path from the light source 102 to the sample 101 and/or from the sample 101 to the polarization sensing camera 410. In some cases, error or malfunction may be detected or identified based at least in part on a sensor signal received from a sensor configured to monitor a mechanical change or vibration in the system 600.

Accordingly, in various embodiments, the systems 500, 502, or in another polarization-based sample characterization system (e.g., the systems 100, 300, 400, 500, 502, and 600 discussed above), the fundamental beam (e.g., the initial beam provided to the beam conditioning optics 103 such as HWP 303a) can be produced by a laser source and may have a wavelength from 700 to 1300 nm, an pulse with of about 20 fs to 200 fs, a repletion rate of 50 to 100 MHz, and an optical power of 0 to 3 W. A half-wave plate (HWP), e.g., HWP 303a, in combination with a laser polarizer (e.g., polarizer 303b) configured to pass horizontally (h) polarized light (e.g., s-polarized light) relative to the wafer surface (e.g., surface of the sample 101), may be used to attenuate the beam intensity, and set the output polarization.

### Optical Interrogation of a Charged Surface

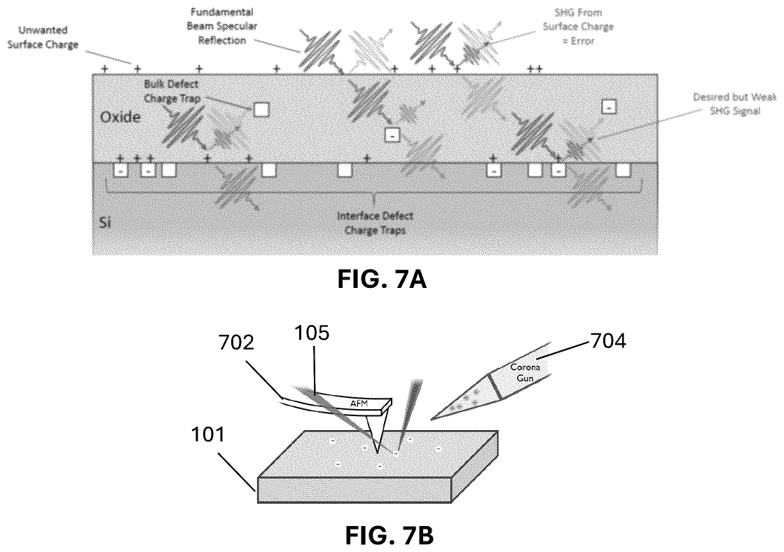

Surface charges are spurious sources of SHG light that cannot be distinguished from those related to the sample properties. Surface charge is largely uncontrolled and may result from many factors such as sample handling and are unrelated to the material or its intrinsic properties. Therefore, it can be useful have to measure and/or control the surface charge that is present at the time of measurement (e.g., characterizing a sample using NOSE). FIG. 7A schematically illustrates a side cross-sectional view of a sample comprising an interface between an oxide layer and a silicon substrate interrogated by incident light that interacts with the air-oxide interface and oxide-silicon interface to generate second-harmonic light that may be received and analyzed by the NOSE systems described above (e.g., system 100, 300, 400, 500, 502, or 600) to characterize one or both of the interfaces. As shown in the figure, accumulation of surface charge one or near these interfaces may affect second harmonic generation and result in erroneous measurement and analysis outcomes (e.g., not associated with the structural features and material composition of the sample).

In some implementations, in any of the configurations described above with respect NOSE and using NOSE for characterizing a sample (e.g., a semiconductor wafer), a surface (e.g., a selected area of a wafer surface) of the sample (e.g., sample 101) can be electrically charged for evaluating and/or manipulating surface charge to improve the reliability and accuracy of the measurement and/or characterization. In some cases, an AFM and/or a corona gun tip may be integrated or disposed at or near the measurement location to provide a means of directly manipulating and/or measuring the surface charge prior to performing NOSE measurement using the above-mentioned configurations. The addition of the AFM or the corona gun to any of the NOSE configurations described above may allow quantitative measurement site charging and/or actively neutralizing charge at the measurement site. Sample charge capacity and SHG as a function of incremental charge may be studied, thus providing a quantitative calibration for specific materials. FIG. 7B schematically illustrates positioning of an AFM tip 702 and a corona gun head 704 with respect to (e.g., proximal or near) a target region on the top major surface of the sample 101 interrogated by an incident optical beam 105. In some cases, the AFM tip 702 can be positioned with respect to sample 101 to obtain one or more measurements from the sample 101 and/or an image of the surface of the sample 101. In some embodiments, the AFM tip 702 may be configured to come in proximity with the sample 101 to obtain a measurement or an assessment of charge on a portion of the sample 101. In some embodiments, the AFM tip 702 may be scanned across a portion of the sample 101.

In some cases, the SHG intensity-reference scheme can be made more accurate by applying the same combined AFM-Corona Gun method as previously described. Referencing characterizes the SHG impact of uncontrollable, short-term laser power drift or fluctuations. This is accomplished by measuring SHG on system-integrated sample chips prior to sample measurement. These have known reflectance and SHG efficiencies and laser power deviations can be converted into SHG counts to be removed from the sample measurement. However, reference chips also carry unknown surface charges that inject error into the reference correction. Mapping or neutralizing charge will allow removal of this error from the Intensity Reference.

In some implementations, any of the configuration described above with respect NOSE and using NOSE for characterizing a sample (e.g., a semiconductor wafer), can be used in a semiconductor manufacturing and/or production line for inline characterization of the semiconductor wafers and the corresponding devices and structures (e.g., electronic devices, integrated circuits) fabricated on these wafers. In some cases, the improved speed of the polarization-based sample characterization enabled by the systems and configurations described above, may allow these systems and configurations to be used (e.g., directly used) in a semiconductor manufacturing and/or production line as an additional or alternative inline system, e.g., replacing a conventional wafer characterization tool. In some cases, implementing of these systems in a semiconductor manufacturing and/or production lines may not significantly affect a manufacturing rate and/or production rate of the corresponding semiconductor manufacturing and/or production lines. In some cases, implementing of these systems in a semiconductor manufacturing and/or production lines may improve a manufacturing rate and/or production rate of the corresponding semiconductor manufacturing and/or production lines.

### Example Embodiments

Example embodiments described herein have several features, no single one of which is indispensable or solely responsible for their desirable attributes. A variety of example systems and methods are provided below.

### Part-1A

Example 1. An optical metrology device capable of determining a characteristic of a sample, the optical metrology device comprising:
a high frequency, scanning polarization state generator, free from moving parts, that converts a pulsed, polarized laser beam to a beam whose output pulses are rapidly and continuously cycling through a selectable range of polarizations states; a long-pass visible blocking filter, focusing optics focusing the beam on the sample (where the second harmonic light, or SHG, is generated), at an angle of incidence between 80° and 30° (selected based on sample type); then passing collection optics to catch the exiting laser beam and the SHG signal generated in the sample; followed by a short pass visible and infrared-blocking filter;
an optional beam splitter to forming either one (no beam splitter), or two, branched analyzer arms that together decompose (potentially completely decompose) the SHG polarization state into relative intensities of its polarization components; the main arm on the direct-pass through the beam splitter (if present), followed (e.g., immediately followed) by a zero-order quarter-wave retarder and a polarizing beam splitter with each of the mutually perpendicular polarizations from the polarizing beam splitter passing another short-pass visible and infrared-blocking filter before terminating in a photomultiplier tube for SHG signal polarization component detection; the secondary arm, if the beam splitter is employed, is reflected 90° from the beam splitter and passes a zero-order half-wave retarder in an automated rotatable mount and a polarizing beam splitter with each perpendicular polarization component beam from the polarizing beam splitter passing a short-pass visible and infrared-blocking filter before terminating in a photomultiplier tube to be detected.

Example 2. The optical metrology device of Example 1, wherein the beam comprises time-varying polarization states and phases of polarization components.

Example 3. The optical metrology device of Example 1, wherein the polarization state generator comprises a polarizer oriented to pass horizontally polarized light as defined relative to the sample wafer surface normal, followed by a photoelastic modulator operating in full or half-wave mode at a cycle rate from 0-100 kHz.

Example 4. The optical metrology device of Example 1, wherein the main analyzing arm comprises a zero-order quarter-wave retarder in an automated rotatable mount, followed by a beam splitting polarizer cube with the horizontal component (as defined relative to the sample wafer surface normal) passing on to a photo multiplier tube which outputs to fast preamplifier and collected using a time-gated photon counting card.

Example 5. The optical metrology device of Example 1, wherein the secondary analyzing arm comprises a zero-order half-wave retarder in an automated rotatable mount, followed by a beam splitting polarizer cube with the horizontal component (as defined relative to the sample wafer surface normal) passing on to a photo multiplier tube which outputs to fast preamplifier and collected using a time-gated photon counting card.

Example 6. The optical metrology device of Example 1, further comprising a 20-100 femtosecond pulse laser light source operating at a 1-100 MHz repetition rate that produces a polarized light beam whose wavelength has been selected to produce the desired second harmonic wavelength in the target material.

Example 7. A method of characterizing a sample using an optical metrology device, the method comprising: Generation of SHG component polarization curves as a function of incident polarization state.

Example 8. The method of Example 7, further comprising determining components of a Nonlinear Susceptibility Tensor (χ⁽²⁾) for the sample using the SHG signal polarization components as a function of incident state.

Example 9. The method of Example 7, further comprising determining components of a Mueller Matrix for the sample computed from the Nonlinear Susceptibility Tensor elements (χ⁽²⁾).

### Part-2A

Example 1. An optical metrology device capable of determining a characteristic of a sample, the optical metrology device comprising: a high frequency, scanning polarization state generator, free from moving parts, that converts a pulsed, polarized laser beam to a beam whose output pulses are rapidly and continuously cycling through a selectable range of polarizations states; a long-pass visible blocking filter, focusing optics focusing the beam on the sample (where the second harmonic light, or SHG, is generated), at an angle of incidence between 80° and 30° (selected based on sample type); then passing collection optics to catch the exiting laser beam and the SHG signal generated in the sample; followed by a short pass visible and infrared-blocking filter; then a nematic, phase-only spatial light modulator with pixels programed in an alternating pattern of half-wave and quarter-wave retardance, this beam then passes to a polarization sensing camera, whose imager pixels are constructed with one of four integrated, wire-grid polarizers in front. Camera pixels or “macro-pixels” comprise four contiguous pixels in a 2×2 arrangement, each having one of the four unique polarizers (0°/180°, 45°/225°, 90°/270° and 135°/315°). This combination simultaneously (and potentially completely) decomposes the SHG polarization state into relative intensities of its polarization components giving a 2D beam profile of the stokes vectors from which the Nonlinear susceptibility Tensor is derived and thence the sample Mueller Matrix.

Example 2. The optical metrology device of Example 1, wherein the beam comprises time-varying polarization states and phases of polarization components.

Example 3. The optical metrology device of Example 1, wherein the polarization state generator comprises a polarizer oriented to pass horizontally polarized light as defined relative to the sample wafer surface normal, followed by a photoelastic modulator operating in full or half-wave mode at a cycle rate from 0-100 kHz.

Example 4. The optical metrology device of Example 1, wherein the analyzing arm comprises an objective lens (OBJ) to collect and collimate the SHG and remaining fundamental light, short-pass filter stack (FS) to block the visible and IR, a nematic, phase-only spatial light modulator with pixels programed in an alternating pattern of half-wave and quarter-wave retardance, a polarization sensing camera, whose pixels or “macro-pixels” comprise four contiguous pixels in a 2×2 arrangement, each passing one of four polarizations (0°/180°, 45°/225°, 90°/270° and 135°/315°).

Example 5. The optical metrology device of Example 1, further comprising a 20-100 femtosecond pulse laser light source operating at a 1-100 MHz repetition rate that produces a polarized light beam whose wavelength has been selected to produce the desired second harmonic wavelength in the target material.

Example 6. A method of characterizing a sample using an optical metrology device, the method comprising: Generation of SHG component polarization curves as a function of incident polarization state.

Example 7. The method of Example 6, further comprising determining components of a Nonlinear Susceptibility Tensor for the sample using the SHG signal polarization components as a function of incident state.

Example 8. The method of Example 6, further comprising determining components of a Mueller Matrix for the sample computed from the Nonlinear Susceptibility Tensor elements.

Example 9. The method of Example 6, further comprising determining the optical constants of the sample from the components of a Mueller Matrix, the Nonlinear Susceptibility Tensor, or SHG intensity such as refractive index, extinction coefficient, film-layer thickness, interface spacing, optical critical dimensions, trapped charge, threshold voltage among others.

Example 10. The method of Example 9, further comprising the two-dimensional distribution or map of the derived sample properties within the beam spot upon the sample.

### Part-2B

Example 1. A sample characterization system for interrogating a sample, said system comprising:
a laser light source configured to output a laser beam to be directed to said sample such that light emanates from said sample;
a polarization state generator positioned to receive the laser beam output by the laser light source to provide a plurality of different polarization states to said light beam that is incident on said sample; and
a detector array comprising a plurality of detectors having differently oriented linear polarizers in front of different detectors and a plurality of retarders disposed in front of said differently oriented linear polarizers such that said light from said sample passes through said plurality of retarders, said differently oriented linear polarizers, and to said plurality of detectors.

Example 2. The system of Example 1, wherein said laser light source is configured to produce a nonlinear output from said sample.

Example 3. The system of Example 1 or 2, wherein said laser light source is configured to produce SHG light from said sample.

Example 4. The system of any of the Examples above, wherein said laser light source comprises a pulsed femtosecond laser.

Example 5. The system of any of the Examples above, wherein the laser light source has sufficiently high power to induce second harmonic generation in said sample.

Example 6. The system of any of the Examples above, wherein said laser light source is configured to output laser pulses at a 1-100 MHz repetition rate.

Example 7. The system of any of the Examples above, wherein said polarization state generator comprises a retarder configured to vary the phase difference introduced in orthogonal polarizations passing through the retarder.

Example 8. The system of any of the Examples above, wherein said polarization state generator comprises a retarder that has a retardance configured to be varied.

Example 9. The system of any of the Examples above, wherein said polarization state generator comprises a photoelastic modulator.

Example 10. The system of any of the Examples above, wherein said polarization state generator is configured to provide variation in polarization states without relying on moving parts.

Example 11. The system of any of the Examples above, wherein said polarization state generator is configured to cycle through different phase differences between orthogonal polarization states.

Example 12. The system of Example 11, wherein said phase differences extend over a range of at least 90°.

Example 13. The system of Example 11, wherein the phase differences extend over a range of at least 180°.

Example 14. The system of any of the Examples above, wherein said differently oriented linear polarizers include linear polarizers orientated at 0°, 90°, 45°, 135° with respect to rows of detectors in said detector array.

Example 15. The system of any of the Examples above, wherein said differently oriented linear polarizers include linear polarizers orientated horizontally, vertically, along a first diagonal, and along a second diagonal opposite to the first diagonal with respect to rows of detectors in said detector array.

Example 16. The system of any of the Examples above, wherein said detector array is included in a polarization sensing camera (PSC).

Example 17. The system of any of the Examples above, wherein said at least one retarder comprises a plurality of half-wave retarders and quarter-wave retarders.

Example 18. The system of any of the Examples above, wherein a half-wave retarder is paired with each of a plurality of four differently oriented linear polarizers.

Example 19. The system of any of the Examples above, wherein a quarter-wave retarder is paired with each of a plurality of four differently oriented linear polarizers.

Example 20. The system of any of the Examples above, wherein a half-wave retarder is paired with a linear polarizer orientated at 0°, a half-wave retarder is paired with a linear polarizer orientated at 90°, a half-wave retarder is paired with a linear polarizer orientated at 45°, and a half-wave retarder is paired with a linear polarizer orientated at 135°.

Example 21. The system of any of the Examples above, wherein a quarter-wave retarder is paired with a linear polarizer orientated at 0°, a quarter-wave retarder is paired with a linear polarizer orientated at 90°, a quarter-wave retarder is paired with a linear polarizer orientated at 45°, and a quarter-wave retarder is paired with a linear polarizer orientated at 135°.

Example 22. The system of any of the Examples above, wherein said plurality of retarders comprises a liquid crystal 2D phase array comprising a plurality of retarders.

Example 23. The optical metrology device of any of Examples 22, wherein said liquid crystal 2D phase array comprises a nematic 2D phase array.

Example 24. The system of Example 22 or 23, wherein said liquid crystal 2D phase array comprises pixels configured to be set to half-wave and quarter-wave retardance.

Example 25. The system of any of Examples 22-24, wherein said liquid crystal 2D phase array is configured to be set in an alternating pattern of pixels of half-wave and quarter-wave retardance.

Example 26. The system of any of the Examples above, wherein a half-wave retardance pixel is paired with each of a plurality of four differently oriented linear polarizers.

Example 27. The system of any of the Examples above, wherein a quarter-wave retardance pixel is paired with each of a plurality of four differently oriented linear polarizers.

Example 28. The system of any of the Examples above, wherein a half-wave retardance pixel is paired with a linear polarizer orientated at 0°, a half-wave retardance pixel is paired with a linear polarizer orientated at 90°, a half-wave retardance pixel is paired with a linear polarizer orientated at 45°, and a half-wave retardance pixel is paired with a linear polarizer orientated at 135°.

Example 29. The system of any of the Examples above, wherein a quarter-wave retardance pixel is paired with a linear polarizer orientated at 0°, a quarter-wave retardance pixel is paired with a linear polarizer orientated at 90°, a quarter-wave retardance pixel is paired with a linear polarizer orientated at 45°, and a quarter-wave retardance pixel is paired with a linear polarizer orientated at 135°.

Example 30. The system of any of the Examples above, wherein signals from said plurality of detectors provide information for determining a Stokes vector.

Example 31. The system of any of the Examples above, wherein signals from said plurality of detectors provide information for determining four Stokes parameters, S0, S1, S2, S3.

Example 32. The system of any of the Examples above, wherein a nonlinear susceptibility tensor can be derived from said Stokes vector.

Example 33. The system of any of the Examples above, wherein a nonlinear susceptibility Tensor can be derived from said Stokes parameters.

Example 34. The system of any of the Examples above, wherein a Mueller Matrix can be derived from said nonlinear susceptibility tensor.

Example 35. The system of any of the Examples, included in-line of a semiconductor fabrication line.

Example 36. The system of any of the Examples, wherein light is produced by said sample as a result of a nonlinear interaction of laser light with said sample, the nonlinear interaction comprising a nonlinear optical effect.

### Part-2C

Example 1. A sample characterization system configured to interrogate a sample, said system comprising:
a light source configured to generate a first light beam incident on the sample;
a polarization sensing camera configured to simultaneously receive different portions of a second light beam generated by the sample, the polarization sensing camera comprising at least three polarization sensitive detector elements, an individual polarization sensitive detector element comprising at least one photodetector and at least one polarizer, polarizers for different ones of the at least three polarization sensitive detector elements being configured to transmit different polarization states; and
at least two optical retarders configured to receive the second light beam and transmit the different portions of the second light beam to the polarization sensing camera, wherein the two retarders comprise different retardances,
wherein, in response to simultaneously receiving different portions of the light beam, the at least three polarization sensitive detector elements generate at least three detector signals from which at least three different polarization parameters can be obtained for characterizing the polarization state of said light from said sample.

Example 2. The system of Example 1, wherein the first light beam comprises a vortex optical beam carrying orbital angular momentum.

Example 3. The system of Example 1 or 2, wherein the first light beam comprises at least two different polarization states.

Example 4. The system of any of Examples 1-3, wherein at least two different wavefront regions of the first light beam comprise different polarization states.

Example 5. The system of any of the Examples above, wherein the three different polarization parameters comprise three different Stokes parameters of the second light beam.

Example 6. The system of any of the Examples above, wherein the three different polarization parameters comprise three independent polarization parameters.

Example 7. The system of any of the Examples above, wherein the second light beam is generated by sample via a nonlinear optical effect.

Example 8. The system of any of the Examples above, wherein the second light beam comprises a second harmonic-frequency with respect to the first light beam.

Example 9. The system of any of the Examples above, wherein four different polarization parameters can be obtained for characterizing the polarization state of said light from said sample from the three detector signals.

Example 10. The system of Example 9, wherein the four different polarization parameters comprise four different Stokes parameters.

Example 11. The system of any of the Examples above, wherein said different retardances comprise a half-wave retardance and a quarter-wave retardance.

### Part-3A

Example 1. An optical metrology device capable of determining a characteristic of a sample, the optical metrology device comprising:
an optical vortex beam polarization state generator (a q-plate followed by a half- or quarter-wave, zero-order retarder) that is free of continuously moving parts and converts the femtosecond pulsed, polarized cylindrical laser beam to beam with a customizable, azimuthally varying continuum of polarization states; a long-pass visible blocking filter, focusing optics focusing the beam on the sample (where the second harmonic light, or SHG, is generated), at an angle of incidence between 80° and 30° (selected based on sample type); then passing collection optics to catch the exiting laser beam and the SHG signal generated in the sample; followed by a short pass visible and infrared-blocking filter; then a nematic, phase-only spatial light modulator with pixels programed in an alternating pattern of half-wave and quarter-wave retardance, this beam then passes to a polarization sensing camera, whose imager pixels are constructed with one of four integrated, wire-grid polarizers in front. Camera pixels or “macro-pixels” comprise four contiguous pixels in a 2×2 arrangement, each having one of the four unique polarizers (0°/180°, 45°/225°, 90°/270° and 135°/315°). This combination simultaneously (and potentially completely) decomposes the SHG polarization state into relative intensities of its polarization components giving a 2D beam profile of the stokes vectors from which the Nonlinear susceptibility Tensor is derived and thence the sample Mueller Matrix.

Example 2. The optical metrology device of Example 1, wherein the beam comprises azimuthally varying phase and polarization states.

Example 3. The optical metrology device of Example 1, wherein the polarization state generator comprises a polarizer oriented to pass horizontally polarized light as defined relative to the sample wafer surface normal, followed by a q-plate (refractive, Fresnel-cone, meta-surface, permanent liquid crystal, or programable nematic SLM) and either a half- or quarter-wave, zero-order retarder that is selected and oriented according to application.

Example 4. The optical metrology device of Example 1, wherein the analyzing arm comprises an objective lens (OBJ) to collect and collimate the SHG and remaining fundamental light, short-pass filter stack (FS) to block the visible and IR, a nematic, phase-only spatial light modulator with pixels programed in an alternating pattern of half-wave and quarter-wave retardance, a polarization sensing camera, whose pixels or “macro-pixels” comprise four contiguous pixels in a 2×2 arrangement, each passing one of four polarizations (0°/180°, 45°/225°, 90°/270° and 135°/315°).

Example 5. The optical metrology device of Example 1, further comprising a 20-100 femtosecond pulse laser light source operating at a 1-100 MHz repetition rate that produces a polarized light beam whose wavelength has been selected to produce the desired second harmonic wavelength in the target material.

Example 6. A method of characterizing a sample using an optical metrology device, the method comprising: Generation of SHG component polarization curves as a function of incident polarization state

Example 7. The method of Example 6, further comprising determining components of a Nonlinear Susceptibility Tensor for the sample using the SHG signal polarization components as a function of incident state.

Example 8. The method of Example 6, further comprising determining components of a Mueller Matrix for the sample computed from the Nonlinear Susceptibility Tensor elements.

Example 9. The method of Example 6, further comprising determining the optical constants of the sample from the components of a Mueller Matrix, the Nonlinear Susceptibility Tensor, or SHG intensity such as refractive index, extinction coefficient, film-layer thickness, interface spacing, optical critical dimensions, trapped charge, threshold voltage among others.

Example 10. The method of Example 9, further comprising the two-dimensional distribution or map of the derived sample properties within the beam spot upon the sample.

Example 11. The optical metrology device of Example 1, wherein a selectable, integrated interferometer comprises, a movable beam splitter that may be inserted before the SLM/q-plate, mirrors to route the fundamental beam to a second, movable beam splitter serving as a beam combiner before the polarization sensing camera and a conventional high-resolution CCD or CMOS camera.

Example 12. A method of characterizing and correcting the system wave-front distortion of the optical metrology device, the method comprising: moving a mirror into the metrology device's sample position while simultaneously moving the beam splitter and beam combiner into position, routing 50% of the beam intensity from just before the q-plate/SLM to and through the beam combiner and into the high-resolution camera. The remaining 50% of the intensity continues along the bam path to the mirror, through the collection optics and to the beam combiner where it is reflected into the high-resolution camera, coaxial to the first beam resulting in an interference pattern which is captured by the camera.

Example 13. The method of Example 12 further comprising computational analysis of the captured interferogram wherein, for instances where a programable SLM q-plate is used, the image is compared to that programed into the SLM and by convolution of the interferogram with selected spatial wavefront distortions with the aim of producing the intended SLM pattern. Once determined, the wavefront distortions may be targeted by optical alignment with direct feedback from the interferometer and those that cannot be physically removed, are applied analytically to the programmed pattern by deconvolution and the resulting pattern becomes the new programmed SLM pattern which pre-corrects for the net wave-front error of the system

### Part-3B

Example 1. A sample characterization system for interrogating a sample, said system comprising:
a laser light source configured to output a laser beam to be directed to said sample such that light emanates from said sample;
a q-plate positioned to receive the laser beam output by the laser light source to produce a polarization vortex beam incident on said sample; and
at least one optical detector and at least one retarder positioned such that said at least one optical detector receives at least some of light from said sample after passing through said at least one retarder.

Example 2. The system of Example 1, wherein said laser light source is configured to produce a nonlinear output from said sample.

Example 3. The system of Example 1 or 2, wherein said laser light source is configured to produce SHG light from said sample.

Example 4. The system of any of the Examples above, wherein said laser light source comprises a pulsed femtosecond laser.

Example 5. The system of any of the Examples above, wherein the laser light source has sufficiently high power to induce second harmonic generation in said sample.

Example 6. The system of any of the Examples above, wherein said laser light source is configured to output laser pulses at a 1-100 MHz repetition rate.

Example 7. The system of any of the Examples above, wherein said at least one detector comprises a plurality of detectors.

Example 8. The system of Example 7, wherein said plurality of detectors comprise a plurality of sensor pixels in a detector array.

Example 9. The system of any of the Examples above, wherein said at least one detector comprises a plurality of detectors having differently oriented linear polarizers in front of different detectors.

Example 10. The system of Example 9, wherein said differently oriented linear polarizers include linear polarizers orientated at 0°, 90°, 45°, 135°.

Example 11. The system of Example 9 or 10, wherein said differently oriented linear polarizer include linear polarizers orientated horizontally, vertically, along a first diagonal, and along a second diagonal opposite to the first diagonal.

Example 12. The system of any of the Examples above, wherein said at least one detector comprises a plurality of detectors included in a polarization sensing camera (PSC).

Example 13. The system of any of the Examples above, wherein said at least one retarder comprises a plurality of half-wave retarders and quarter-wave retarders.

Example 14. The system of any of the Examples above, wherein a half-wave retarder is paired with each of a plurality of four differently oriented linear polarizers.

Example 15. The system of any of the Examples above, wherein a quarter-wave retarder is paired with each of a plurality of four differently oriented linear polarizers.

Example 16. The system of any of the Examples above, wherein a half-wave retarder is paired with a linear polarizer orientated at 0°, a half-wave retarder is paired with a linear polarizer orientated at 90°, a half-wave retarder is paired with a linear polarizer orientated at 45°, and a half-wave retarder pixel is paired with a linear polarizer orientated at 135°.

Example 17. The system of any of the Examples above, wherein a quarter-wave retarder is paired with a linear polarizer orientated at 0°, a quarter-wave retarder is paired with a linear polarizer orientated at 90°, a quarter-wave retarder is paired with a linear polarizer orientated at 45°, and a quarter-wave retarder is paired with a linear polarizer orientated at 135°.

Example 18. The system of any of the Examples above, wherein said at least one retarder comprises a liquid crystal 2D phase array comprising a plurality of retarders.

Example 19. The system of Example 20, wherein said liquid crystal 2D phase array comprises a nematic 2D phase array.

Example 20. The system of Example 20 or 21, wherein said liquid crystal 2D phase array comprises pixels configured to be set to half-wave and quarter-wave retardance.

Example 21. The system of any of Examples 20-22, wherein said liquid crystal 2D phase array is configured to be set in an alternating pattern of pixels of half-wave and quarter-wave retardance.

Example 22. The system of any of the Examples above, wherein a half-wave retardance pixel is paired with each of a plurality of four differently oriented linear polarizers.

Example 23. The system of any of the Examples above, wherein a quarter-wave retardance pixel is paired with each of a plurality of four differently oriented linear polarizers.

Example 24. The system of any of the Examples above, wherein a half-wave retardance pixel is paired with a linear polarizer orientated at 0°, a half-wave retardance pixel is paired with a linear polarizer orientated at 90°, a half-wave retardance pixel is paired with a linear polarizer orientated at 45°, and a half-wave retardance pixel is paired with a linear polarizer orientated at 135°.

Example 25. The system of any of the Examples above, wherein a quarter-wave retardance pixel is paired with a linear polarizer orientated at 0°, a quarter-wave retardance pixel is paired with a linear polarizer orientated at 90°, a quarter-wave retardance pixel is paired with a linear polarizer orientated at 45°, and a quarter-wave retardance pixel is paired with a linear polarizer orientated at 135°.

Example 26. The system of any of the Examples above, wherein said at least one optical detector comprises a plurality of optical detectors and said at least one retarder comprises a plurality of retarders positioned such that said plurality of optical detectors receives at least some light from said sample after passing through said plurality of retarders.

Example 27. The system of any of the Example above, further comprising a first beamsplitter positioned to receive light from said sample and split said light into first and second arms.

Example 28. The system of Example 29, wherein said first beamsplitter comprises a partially polarizing beamsplitter.

Example 29. The system of Example 29 or 30, further comprising a second beamsplitter in said first arm positioned to receive light from said first beamsplitter and split said light into two paths toward two separate detectors.

Example 30. The system of Example 31, wherein said second beamsplitter comprises a polarization beamsplitter.

Example 31. The system of Example 31 or 32, further comprising a retarder in said first arm between said first and second beamsplitters.

Example 32. The system of Example 31 or 32, further comprising a full wave retarder in said first arm between said first and second beamsplitters.

Example 33. The system of any of Examples 29-34, further comprising a third beamsplitter in said second arm positioned to receive light from said first beamsplitter and split said light into two paths toward two separate detectors.

Example 34. The system of Example 35, wherein said third beamsplitter comprises a polarization beamsplitter.

Example 35. The system of Example 35 or 36, further comprising a retarder in said third arm between said first and third beamsplitters.

Example 36. The system of Example 35 or 36, further comprising a quarter wave retarder in said third arm between said first and third beamsplitters.

Example 37. The system of any of the Examples above, wherein at least one detector comprises a plurality of photomultiplier tubes (PMT).

Example 38. The system of any of the Examples above, wherein signals from said at least one detector provides information for determining a Stokes vector.

Example 39. The system of any of the Examples above, wherein signals from said at least one detector provides information for determining Stokes parameters.

Example 40. The system of any of the Examples above, wherein signals from said at least one detector provides information for determining four Stokes parameters, S0, S1, S2, S3.

Example 41. The system of any of the Examples above, wherein a nonlinear susceptibility tensor can be derived from said Stokes vector.

Example 42. The system of any of the Examples above, wherein a nonlinear susceptibility Tensor can be derived from said Stokes parameter.

Example 43. The system of any of the Examples above, wherein a Mueller Matrix can be derived from said nonlinear susceptibility tensor.

Example 44. The system of any of the Examples above, wherein said polarization vortex beam has a plurality of different polarization states at different azimuthal locations about a cross-section of said vortex beam orthogonal to propagation of said vortex beam.

Example 45. The system of any of the Examples above, wherein said polarization vortex beam has an orbital angular momentum and different polarization states across a cross-section of the beam orthogonal to the propagation of the beam.

Example 46. The system of any of the Examples above, further comprising a retarder configured to receive the laser beam output by the laser light source from the q-plate.

Example 47. The system of Example 46, wherein said retarder is mounted on a rotatable stage such that said retarder can rotate to provide different polarization states in a cross-section of said vortex beam.

Example 48. The system of Example 46 or 47, wherein said retarder comprises a quarter wave retarder.

Example 49. The system of any of the Examples above, wherein said q-plate comprises a refractive or Fresnel element, meta surface or diffraction grating.

Example 50. The system of any of Examples 1-48, wherein said q-plate comprises a spatial light modulator comprising a plurality of pixels that can be modulated.

Example 51. The system of Example 50, further comprising control electronics configured to control the modulation of said pixels of said spatial light modulator.

Example 52. The system of Examples 51, wherein said spatial light modulator comprising said q-plate and said electronics controlling said pixels of said spatial light modulator are configured to provide a retardance distribution across said spatial light modulator to produce said vortex beam.

Example 53. The system of Examples 51, wherein said spatial light modulator comprising said q-plate and said electronics controlling said pixels of said spatial light modulator are configured to form a diffraction pattern with said pixels of said spatial light modulator.

Example 54. The system of Example 53, wherein said diffraction pattern comprises a forked grating.

Example 55. The system of any of Examples 50-54, wherein said spatial light modulator comprising said q-plate comprises a liquid crystal spatial light modulator.

Example 56. The system of any of Examples 50-55, wherein said spatial light modulator comprises a phase spatial light modulator configured to vary the phase of light transmitted through or reflected from said pixels of said spatial light modulator so as to form a grating.

Example 57. The system of any of Examples 50-56, further configured to interfere said laser light from said laser light source that is directed to said spatial light modulator comprising said q-plate with laser light that is transmitted through or reflected from said spatial light modulator.

Example 58. The system of any of Examples 50-57, further comprising a first beamsplitter disposed to receive a portion of said laser light from said laser light source that is directed to said spatial light modulator.

Example 59. The system of Example 58, further comprising a second beamsplitter disposed to receive and redirected a portion of said laser light transmitted through or reflected from said spatial light modulator.

Example 60. The system of Example 59, further comprising a sensor array configured to receive light from said first and second beamsplitters to detect an interference pattern formed from said light from said first and second beamsplitters.

Example 61. The system of any of Examples 60, further comprising sensor array electronics in electrical communication with said sensor array and in electrical communication with control electronics for controlling said spatial light modulator to alter the state of pixels in the spatial light modulator based on said interference pattern.

Example 62. The system of any of the Examples, included in-line of a semiconductor fabrication line.

Example 63. The system of any of the Examples, wherein light is produced by said sample as a result of a nonlinear effect of laser light from said laser light source being incident on said sample.

### Part 3-C

Example 1. A sample characterization system configured to interrogate a sample, said system comprising:
a light source configured to generate a first light beam incident on the sample, the first light beam comprising a vortex light beam comprising at least two different polarization states;
a plurality of detectors configured to simultaneously receive at least two different wavefront portions of a second light beam from said sample in response of said sample receiving the first light beam, said plurality of detectors configured to generate at least two different detector signals indicative of the intensity to the two different wavefront portions, the two different wavefront portions generated by the sample in response to receiving different ones of the at least two different polarization states.

Example 2. The system of Example 1, wherein said plurality of detectors comprises a detector array comprising a plurality of detector elements.

Example 3. The system of Example 1, further comprising a q-plate positioned to receive said first light beam so as to produce said vortex light beam.

Example 4. The system of Example 3, wherein said q-plate comprises a refractive or Fresnel element, meta surface or diffraction grating.

Example 5. The system of Example 3, wherein said q-plate comprises a spatial light modulator comprising a plurality of pixels that can be modulated.

Example 6. The system of Example 5, further comprising control electronics configured to control the modulation of said pixels of said spatial light modulator.

Example 7. The system of Examples 6, wherein said spatial light modulator comprising said q-plate and said electronics controlling said pixels of said spatial light modulator are configured to provide a retardance distribution across said spatial light modulator to produce said vortex light beam.

Example 8. The system of Examples 6, wherein said spatial light modulator comprising said q-plate and said electronics controlling said pixels of said spatial light modulator are configured to form a diffraction pattern with said pixels of said spatial light modulator.

Example 9. The system of Example 8, wherein said diffraction pattern comprises a forked grating.

Example 10. The system of any of Examples 5-9, wherein said spatial light modulator comprising said q-plate comprises a liquid crystal spatial light modulator.

### Part 4-A

Example 1. An optical metrology device capable of determining a characteristic of a sample, the optical metrology device comprising:
an optical ellipsometer configured to be included in-line of a semiconductor fabrication line to determine a characteristic of a sample by measuring nonlinearly generated light from the sample, said sample comprising a semiconductor wafer,
wherein the optical ellipsometer comprises at least three optical detectors that generate three measured signals for obtaining to three different polarization parameters for the nonlinearly generated light from the sample.

Example 2. The optical metrology device of Example 1, wherein said optical ellipsometer comprises a laser light source.

Example 3. The optical metrology device of Example 2, wherein said laser light source is configured to direct a laser light beam onto said sample.

Example 4. The optical metrology device of Example 2 or 3, wherein said laser light source is configured to produce a nonlinear output from said sample.

Example 5. The optical metrology device of Example 4, wherein said characteristic of said sample is determined based on measurements on said nonlinear output.

Example 6. The optical metrology device of any of Examples 2-5, wherein said laser light source is configured to produce SHG light from said sample.

Example 7. The optical metrology device of Example 6, wherein said characteristic of said sample is determined based on measurements on said SHG light.

Example 8. The optical metrology device of any of Examples 2-7, wherein said laser light source comprises a pulsed laser.

Example 9. The optical metrology device of any of Examples 2-8, wherein said laser light source comprises a pulsed femtosecond laser.

Example 10. The optical metrology device of any of Examples 2-9, wherein said laser light source is configured to output 20-100 femtosecond laser pulses.

Example 11. The optical metrology device of any of Examples 2-10, wherein the laser light source has sufficiently high power to induce second harmonic generation in said sample.

Example 12. The optical metrology device of any of Examples 2-10, wherein the laser light source output laser pulses having sufficiently high energy to induce second harmonic generation in said sample.

Example 13. The optical metrology device of any of Examples 2-12, wherein said laser light source is configured to output laser pulses at a 1-100 MHz repetition rate.

Example 14. The optical metrology device of any of Examples 2-13, wherein the laser light source outputs a polarized laser beam.

Example 15. The optical metrology device of any of Examples 3-14, wherein the laser beam is configured to be directed onto said sample comprises time-varying polarization states and phases of polarization components.

Example 16. The optical metrology device of any of the Examples above, further comprising a polarization state generator configured to vary the polarization of light incident on said sample.

Example 17. The optical metrology device of any of Examples 3-15, further comprising a polarization state generator configured to receive said laser beam from said laser light source and provide a plurality of different polarization states to the light beam output therefrom and directed onto said sample.

Example 18. The optical metrology device of Examples 16 or 17, wherein said polarization state generator comprises a retarder configured to vary the phase difference introduced in orthogonal polarization passing through the retarder.

Example 19. The optical metrology device of Example 16 or 17, wherein said polarization state generator comprises a retarder configured to be rotated.

Example 20. The optical metrology device of Examples 16 or 17, wherein polarization state generator comprises a retarder that has a retardance configured to be varied.

Example 21. The optical metrology device of Examples 16 or 17, wherein said polarization state generator comprises a photoelastic modulator.

Example 22. The optical metrology device of Examples 16 or 17, wherein said polarization state generator comprises a liquid crystal modulator.

Example 23. The optical metrology device of Examples 16 or 17, wherein said polarization state generator comprises a liquid crystal spatial light modulator.

Example 24. The optical metrology device of any of Examples 16-23, wherein said polarization state generator is configured to provide variation in polarization states without relying on moving parts.

Example 25. The optical metrology device of any of Examples 16-24, wherein said polarization state generator is configured to cycle through a plurality of polarization states.

Example 26. The optical metrology device of any of Examples 16-25, wherein said polarization state generator is configured to cycle through elliptical polarization states.

Example 27. The optical metrology device of any of Examples 16-26, wherein said polarization state generator is configured to cycle through a plurality of linear and elliptical polarization states.

Example 28. The optical metrology device of any of Examples 16-27, wherein said polarization state generator is configured to cycle through a plurality of linear, elliptical, and circular polarization states.

Example 29. The optical metrology device of any of Examples 16-28, wherein said polarization state generator is configured to cycle through different phase differences between orthogonal polarization states.

Example 30. The optical metrology device of Example 29, wherein said phase differences extend over a range of at least 90°.

Example 31. The optical metrology device of Example 29, wherein the phase differences extend over a range of at least 180°.

Example 32. The optical metrology device of Example 29, wherein said polarization state generator is configured to cycle through a plurality of phase differences from 0 to π radians between orthogonal polarization states.

Example 33. The optical metrology device of any of the Examples above, further comprising focusing optics configured to focus the laser light beam onto said sample.

Example 34. The optical metrology device of Example 33, wherein said focusing optics comprises a lens.

Example 35. The optical metrology device of Example 33, wherein said focusing optics comprises an objective lens.

Example 36. The optical metrology device of any of the Examples above, further comprising collection optics configured to collect light from said sample.

Example 37. The optical metrology device of any of the Examples above, further comprising collection optics configured to collect said SHG light from said sample.

Example 38. The optical metrology device of Example 36 or 37, wherein said collection optics comprises a lens.

Example 39. The optical metrology device of Example 36 or 37, wherein said collection optics comprises an objective lens.

Example 40. The optical metrology device of any of the Examples above, further comprising at least one retarder positioned with respect to at least one of said optical detectors such that said at least one optical detector receives at least some of light from said sample after passing through said at least one retarder.

Example 41. The optical metrology device of any of the Examples above, further comprising at least one retarder positioned with respect to at least two of said optical detectors such that said at least two optical detector receives at least some of light from said sample after passing through said at least one retarder.

Example 42. The optical metrology device of Example 41, wherein said at least three optical detectors comprise a plurality of sensor pixels in a detector array.

Example 43. The optical metrology device of any of Examples 40-42, wherein said at least three detectors have differently oriented linear polarizers in front of the different detectors.

Example 44. The optical metrology device of Example 43, wherein said at least three optical detectors comprise four optical detectors and said differently oriented linear polarizer include linear polarizers orientated at 0°, 90°, 45°, 135°.

Example 45. The optical metrology device of Example 44, wherein said differently oriented linear polarizer include linear polarizers orientated horizontally, vertically, along a first diagonal, along a second diagonal opposite to the first diagonal.

Example 46. The optical metrology device of any of Examples 40-45, wherein said at least three detectors are included in a polarization sensing camera (PSC).

Example 47. The optical metrology device of any of Examples 40-46, wherein said at least one retarder comprises a plurality of half-wave retarders and quarter-wave retarders.

Example 48. The optical metrology device of any of claims 40-47, wherein a half-wave retarder is with paired each of a plurality of four differently oriented linear polarizers.

Example 49. The optical metrology device of any of claims 40-48, wherein a quarter-wave retarder is paired with each of a plurality of four differently oriented linear polarizers.

Example 50. The optical metrology device of any of claims 40-49, wherein at least one half-wave retardance pixel is paired with each of a plurality of four differently oriented linear polarizers.

Example 51. The optical metrology device of any of claims 40-50, wherein at least one quarter-wave retardance pixel is paired with each of a plurality of four differently oriented linear polarizers.

Example 52. The optical metrology device of any of claims 40-51, wherein a half-wave retardance pixel is paired with a linear polarizer orientated at 0°, a half-wave retardance pixel is paired with a linear polarizer orientated at 90°, a half-wave retardance pixel is paired with a linear polarizer orientated at 45°, and a half-wave retardance pixel is paired with a linear polarizer orientated at 135°.

Example 53. The optical metrology device of any of claims 40-52, wherein a quarter-wave retardance pixel is paired with a linear polarizer orientated at 0°, a quarter-wave retardance pixel is paired with a linear polarizer orientated at 90°, a quarter-wave retardance pixel is paired with a linear polarizer orientated at 45°, and a quarter-wave retardance pixel is paired with a linear polarizer orientated at 135°.

Example 54. The optical metrology device of any of Examples 40-53, wherein said at least one retarder comprises a liquid crystal 2D phase array comprising a plurality of retarders.

Example 55. The optical metrology device of any of Examples 54, wherein said liquid crystal 2D phase array comprises a nematic 2D phase array.

Example 56. The optical metrology device of Example 54 or 55, wherein said liquid crystal 2D phase array comprises pixels configured to be set to half-wave and quarter-wave retardance.

Example 57. The optical metrology device of any of claims 54-56, wherein said liquid crystal 2D phase array is configured to be set in an alternating pattern of pixels of half-wave and quarter-wave retardance.

Example 58. The optical metrology device of any of claims 43-57, wherein a half-wave retardance pixel is paired with each of a plurality of four differently oriented linear polarizers.

Example 59. The optical metrology device of any of claims 43-58, wherein a quarter-wave retardance pixel is paired with each of a plurality of four differently oriented linear polarizers.

Example 60. The optical metrology device of any of claims 40-59, wherein a half-wave retardance pixel is paired with a linear polarizer orientated at 0°, a half-wave retardance pixel is paired with a linear polarizer orientated at 90°, a half-wave retardance pixel is paired with a linear polarizer orientated at 45°, and a half-wave retardance pixel is paired with a linear polarizer orientated at 135°.

Example 61. The optical metrology device of any of claims 40-60, wherein a quarter-wave retardance pixel is paired with a linear polarizer orientated at 0°, a quarter-wave retardance pixel is paired with a linear polarizer orientated at 90°, a quarter-wave retardance pixel is paired with a linear polarizer orientated at 45°, and a quarter-wave retardance pixel is paired with a linear polarizer orientated at 135°.

Example 62. The optical metrology device of Examples 40-61, wherein said at least one retarder comprises a plurality of retarders positioned such that said at least three optical detectors receives at least some light from said sample after passing through one of said plurality of retarders.

Example 63. The optical metrology device of Example 41-62, further comprising a first beamsplitter positioned to receive light from said sample and split said light into first and second arms.

Example 64. The optical metrology device of Example 63, wherein said first beamsplitter comprises a partially polarizing beamsplitter.

Example 65. The optical metrology device of Example 63 or 64, further comprising a second beamsplitter in said first arm positioned to receive light from said first beamsplitter and split said light into two paths toward two separate detectors.

Example 66. The optical metrology device of Example 65, wherein said second beamsplitter comprises a polarization beamsplitter.

Example 67. The optical metrology device of Example 65 or 66, further comprising a retarder in said first arm between said first and second beamsplitters.

Example 68. The optical metrology device of Example 65 or 66, further comprising a full wave retarder in said first arm between said first and second beamsplitters.

Example 69. The optical metrology device of any of Examples 63-68, further comprising a third beamsplitter in said second arm positioned to receive light from said first beamsplitter and split said light into two paths toward two separate detectors.

Example 70. The optical metrology device of Example 69, wherein said third beamsplitter comprises a polarization beamsplitter.

Example 71. The optical metrology device of Example 69 or 70, further comprising a retarder in said second arm between said first and third beamsplitters.

Example 72. The optical metrology device of Example 69 or 70, further comprising a quarter wave retarder in said second arm between said first and third beamsplitters.

Example 73. The optical metrology device of any of the Examples above, wherein said detectors comprise photomultiplier tubes (PMT).

Example 74. The optical metrology device of any of the Examples above, wherein signals from said at least three optical detectors provide information for determining Stokes parameters.

Example 75. The optical metrology device of any of the Examples above, wherein signals from said at least three optical detectors provide information for determining a Stokes vector.

Example 76. The optical metrology device of any of the Examples above, wherein signals from said optical detectors provide information for determining four Stokes parameters, S0, S1, S2, S3.

Example 77. The optical metrology device of Example 75, wherein a nonlinear susceptibility tensor can be derived from said Stokes vector.

Example 78. The optical metrology device of Example 74 or 76, wherein a nonlinear susceptibility Tensor can be derived from said Stokes parameters.

Example 79. The optical metrology device of Example 77 or 78, wherein a Mueller Matrix can be derived from said nonlinear susceptibility tensor.

Example 80. The optical metrology device of any of the Examples 1-14 or 33-79, further comprising a q-plate configured to produce a polarization vortex beam incident on said sample.

Example 81. The optical metrology device of any of Examples 3-15 or 33-78, further comprising a q-plate positioned to receive said laser beam from said laser light source so as to produce a polarization vortex beam having a plurality of different polarization states.

Example 82. The optical metrology device of Example 80 or 81, wherein further comprising a retarder positioned to received light from said q-plate, said retarder being mounted on a rotatable stage such that said retarder can rotate to provide different polarization state in the vortex beam.

Example 83. The optical metrology device of any of the Examples 80-82, wherein said polarization vortex beam has an orbital angular momentum and different polarization states across a cross-section of the beam orthogonal to the propagation of the beam.

Example 84. The optical metrology device of any of the Examples 80-83, wherein said retarder comprises a quarter wave retarder.

Example 85. The optical metrology device of any of Examples 80-84, wherein said q-plate comprises a refractive or Fresnel element, meta surface or diffraction grating.

Example 86. The optical metrology device of any of Examples 80-84, wherein said q-plate comprises a spatial light modulator comprising a plurality of pixels that can be modulated.

Example 87. The optical metrology device of Example 86, further comprising control electronics configured to control the modulation of said pixels of said spatial light modulator.

Example 88. The optical metrology device of Example 87, wherein said spatial light modulator comprising said q-plate and said electronics controlling said pixels are configured to form a diffraction pattern with said pixels of said spatial light modulator.

Example 89. The optical metrology device of Example 88, wherein said diffraction pattern comprises a forked grating.

Example 90. The optical metrology device of any of Examples 86-89, wherein said spatial light modulator comprising said q-plate comprises a liquid crystal spatial light modulator.

Example 91. The optical metrology device of any of Examples 86-90, wherein said spatial light modulator comprises a phase spatial light modulator configured to vary the phase of light transmitted through or reflected from said pixels of said spatial light modulator so as to form a grating.

Example 92. The optical metrology device of any of Examples 86-91, further configured to interfere said laser light from said laser light source that is directed to said spatial light modulator comprising said q-plate with laser light that is transmitted through or reflected from said spatial light modulator.

Example 93. The optical metrology device of any of Examples 86-92, further comprising a first beamsplitter disposed to receive redirected a portion of said laser light from said laser light source that is directed toward said spatial light modulator.

Example 94. The optical metrology device of Example 93, further comprising a second beamsplitter disposed to receive and redirected a portion of said laser light transmitted through or reflected from said spatial light modulator.

Example 95. The optical metrology device of Example 94, further comprising a sensor array configured to receive light from said first and second beamsplitters to detect an interference pattern formed from light from said first and second beamsplitters.

Example 96. The optical metrology device of any of Examples 95, further comprising sensor array electronics in electrical communication with said sensor array and in electrical communication with control electronics for controlling said spatial light modulator to alter the state of pixels in the spatial light modulator based on said interference pattern.

Example 97. The optical metrology device of any of the Examples, included in-line of a semiconductor fabrication line.

Example 98. The optical metrology device of any of Examples 74-97, wherein the signals from said at least three detectors that provide information for determining the Stokes vector for a polarization state of light from said sample are generated during a readout period of the detectors.

Example 99. The optical metrology device of any of Examples 74-98, wherein the signals from said at least three detectors that provide information for determining the Stokes vector for a polarization state of light from said sample are generated in less than 20 milliseconds.

Example 100. The optical metrology device of any of Examples 74-98, wherein the signals from said at least three detectors that provide information for determining the Stokes vector for a polarization state of light from said sample are generated in less than 1 milliseconds.

Example 101. The optical metrology device of Example 74, wherein the signals provide information for determining a nonlinear susceptibility tensor for the sample.

Example 102. The optical metrology device of any of the Examples above, wherein the signals provide information for determining a plurality of Stokes vectors and the nonlinear susceptibility tensor is derived based on the plurality of Stokes vectors.

Example 103. The optical metrology device of any of the Examples above, wherein sensing regions of the plurality of detectors are substantially parallel or coplanar.

Example 104. The optical metrology device of any of the Examples above, wherein the at least three optical detectors are fabricated on the same substrate.

Example 105. The optical metrology device of any of the Examples above, wherein the at least three detectors generate the three measured signals in response to simultaneously receiving the nonlinearly generated light.

Example 106. The optical metrology device of any of the Examples above, wherein the at least three detectors generate the three measured signals simultaneously.

Example 107. The optical metrology device of any of the Examples above, wherein the three measured signals are generated in response to receiving three different wavefront portions of nonlinearly generated light having different polarization states.

Example 108. The optical metrology device of any of the Examples above, wherein the at least three detectors comprise at least three detector elements in a detector array and the three measured signals are generated by different ones of the three detector elements.

Example 109. The optical metrology device of Example 108, wherein the three measured signals are generated during a single readout period of the photodetector array.

Example 110. The optical metrology device of Example 108 or 109, wherein the three measured signals are generated in less than 20 millisecond.

Example 111. The optical metrology device of Example 108 or 109, wherein the three measured signals are generated in less than 1 milliseconds.

Example 112. The optical metrology device of any of the Examples above, wherein the photodetectors comprises a CCD sensor.

Example 113. The optical metrology device of any of the Examples above, wherein the photodetectors comprises a CMOS sensor.

Example 114. The optical metrology device of any of the Examples above, wherein the at least three optical detectors are included in a detector array that is planar.

Example 115. The optical metrology device of Example 114, wherein the three photodetector elements are fabricated on the same substrate.

Example 116. The optical metrology device of the Examples above, wherein said semiconductor wafer is included in a process for forming integrated circuits thereon.

Example 117. The optical metrology device of the Examples above, wherein said semiconductor wafer has integrated circuits formed thereon.

### Part 4-B

Example 1. A sample characterization system configured to interrogate a sample, said system comprising:
a laser light source configured to output a laser beam to be directed to said sample, said laser beam having sufficient energy to induce a nonlinear optical effect and produce light from said sample as a result of said nonlinear optical effect;
polarization optics positioned to receive the laser beam output by the laser light source to provide laser light having a plurality of polarization states to said light beam that is incident on said sample; and
at least one optical detector and at least one retarder positioned such that said at least one optical detector receives at least some of the light produced as the result of said nonlinear optical effect, from said sample after passing through said at least one retarder, said at least one optical detector and said at least one retarder configured to obtain at least three measurements to provide at least three parameters for characterizing the polarization state of said light from said sample;
wherein said system is configured to be included in-line of a semiconductor fabrication line to determine a characteristic of a sample comprising a semiconductor wafer.

Example 2. The system of Example 1, wherein said at least one optical detector comprises a plurality of detectors.

Example 3. The system of Example 2, wherein said plurality of detectors comprise a plurality of sensor pixels in a detector array.

Example 4. The system of any of the Examples above, wherein said at least one optical detector and said at least one retarder comprise at least three optical detectors and at least two retarders.

Example 5. The system of any of the Examples above, wherein said at least one detector comprises a plurality of detectors having differently oriented linear polarizers in front of different detectors.

Example 6. The system of any of the Examples above, wherein said at least one optical detector comprises at least four detectors having differently oriented linear polarizers in front of different detectors.

Example 7. The system of Example 5 or 6, wherein said differently oriented linear polarizers include linear polarizers orientated at 0°, 90°, 45°, 135°.

Example 8. The system of Example 5 or 6, wherein said differently oriented linear polarizers include linear polarizers orientated horizontally, vertically, along a first diagonal, along a second diagonal opposite to the first diagonal.

Example 9. The system of any of the Examples above, wherein said at least one detector comprises a plurality of detectors included in a polarization sensing camera (PSC).

Example 10. The system of any of the Examples above, wherein said at least one retarder comprises a plurality of half-wave retarders and quarter-wave retarders.

Example 11. The system of any of the Examples above, wherein a half-wave retarder is paired with each of a plurality of four differently oriented linear polarizers.

Example 12. The system of any of the Examples above, wherein a quarter-wave retarder is paired with each of a plurality of four differently oriented linear polarizers.

Example 13. The system of any of the Examples above, wherein a half-wave retarder is paired with a linear polarizer orientated at 0°, a half-wave retarder is paired with a linear polarizer orientated at 90°, a half-wave retarder is paired with a linear polarizer orientated at 45°, and a half-wave retarder pixel is paired with a linear polarizer orientated at 135°.

Example 14. The system of any of the Examples above, wherein a quarter-wave retarder is paired with a linear polarizer orientated at 0°, a quarter-wave retarder is paired with a linear polarizer orientated at 90°, a quarter-wave retard is paired with a linear polarizer orientated at 45°, and a quarter-wave retarder is paired with a linear polarizer orientated at 135°.

Example 15. The system of any of the Examples above, wherein said at least one retarder comprises a liquid crystal 2D phase array comprising a plurality of retarders.

Example 16. The system of Example 15, wherein said liquid crystal 2D phase array comprises a nematic 2D phase array.

Example 17. The system of Example 15 or 16, wherein said liquid crystal 2D phase array comprises pixels configured to be set to half-wave and quarter-wave retardance.

Example 18. The system of any of claims 15-17, wherein said liquid crystal 2D phase array is configured to be set in an alternating pattern of pixels of half-wave and quarter-wave retardance.

Example 19. The system of any of the Examples above, wherein a half-wave retardance pixel is paired with each of a plurality of four differently oriented linear polarizers.

Example 20. The system of any of the Examples above, wherein a quarter-wave retardance pixel is paired with each of a plurality of four differently oriented linear polarizers.

Example 21. The system of any of the Examples above, wherein a half-wave retardance pixel is paired with a linear polarizer orientated at 0°, a half-wave retardance pixel is paired with a linear polarizer orientated at 90°, a half-wave retardance pixel is paired with a linear polarizer orientated at 45°, and a half-wave retardance pixel is paired with a linear polarizer orientated at 135°.

Example 22. The system of any of the Examples above, wherein a quarter-wave retardance pixel is paired with a linear polarizer orientated at 0°, a quarter-wave retardance pixel is paired with a linear polarizer orientated at 90°, a quarter-wave retardance pixel is paired with a linear polarizer orientated at 45°, and a quarter-wave retardance pixel is paired with a linear polarizer orientated at 135°.

Example 23. The system of any of the Examples above, wherein said at least one optical detector and said at least one retarder comprise a plurality of optical detectors and a plurality of retarders positioned such that said plurality of optical detectors receives at least some light from said sample after passing through said plurality of retarders.

Example 24. The system of any of the Examples above, further comprising a first beamsplitter positioned to receive light from said sample and split said light into first and second arms.

Example 25. The system of Example 24, wherein said first beamsplitter comprises a partially polarizing beamsplitter.

Example 26. The system of Example 24 or 25, further comprising a second beamsplitter in said first arm positioned to receive light from said first beamsplitter and split said light into two paths toward two separate detectors.

Example 27. The system of Example 26, wherein said second beamsplitter comprises a polarization beamsplitter.

Example 28. The system of any of Examples 26-27, further comprising a retarder in said first arm between said first and second beamsplitters.

Example 29. The system device of any of Examples 26-27, further comprising a full wave retarder in said first arm between said first and second beamsplitters.

Example 30. The system of any of Examples 24-29, further comprising a third beamsplitter in said second arm positioned to receive light from said first beamsplitter and split said light into two paths toward two separate detectors.

Example 31. The system of Example 30, wherein said third beamsplitter comprises a polarization beamsplitter.

Example 32. The system of Example 30 or 31, further comprising a retarder in said second arm between said first and third beamsplitters.

Example 33. The system of Example 30 or 31, further comprising a quarter wave retarder in said second arm between said first and third beamsplitters.

Example 34. The system of the any of the Examples above, wherein said at least one optical detector comprises a plurality of photomultiplier tubes (PMT).

Example 35. The system of any of the Examples above, wherein said at least three parameters can be used to determine a Stokes vector.

Example 36. The system of any of the Examples above, wherein said at least three parameters can determine a Stokes vector.

Example 37. The system of any of the Examples above, wherein said at least three parameters comprise four Stokes parameters, S0, S1, S2, S3.

Example 38. The system of any of the Examples above, wherein said at least three parameters comprise equivalents of the four Stokes parameters, S0, S1, S2, S3.

Example 39. The system of any of the Examples above, wherein said at least three parameters can be used to determine a nonlinear susceptibility tensor.

Example 40. The system of any of the Examples above, wherein a nonlinear susceptibility tensor can be derived from said three parameters.

Example 41. The system of Example 39 or 40, wherein a Mueller Matrix can be derived from said nonlinear susceptibility tensor.

Example 42. The system of any of the Examples above, wherein said three parameters can be used to determine a Mueller Matrix.

Example 43. The system of any of the Examples above, wherein said at least three parameters comprises at least four parameters and the polarization state of the light emitted from said sample can be completely specified with respect to the Poincare sphere by said four parameters.

Example 44. The system of any of the Examples above, wherein said at least three parameters comprises at least four parameters and the polarization state of the light emitted from said sample can be completely specified by said four parameters.

Example 45. The system of any of the Examples above, wherein said polarization optics comprises a polarization state generator configured to receive said laser beam from said laser light source and provide a plurality of different polarization states to the light beam output therefrom and directed onto said sample.

Example 46. The system of Example 45, wherein said polarization state generator comprises a retarder configured to vary the phase difference introduced in orthogonal polarization passing through the retarder.

Example 47. The system of Examples 45 or 46, wherein said polarization state generator comprises a retarder configured to be rotated.

Example 48. The system of Examples 45 or 46, wherein polarization state generated comprises a retarder that has a retardance configured to be varied.

Example 49. The system of Examples 45 or 46, wherein said polarization state generator comprises a photoelastic modulator.

Example 50. The system of Examples 45 or 46, wherein said polarization state generator comprises a liquid crystal modulator.

Example 51. The system of Examples 45 or 46, wherein said polarization state generator comprises a liquid crystal spatial light modulator.

Example 52. The system of any of Examples 45-51, wherein said polarization state generator is configured to provide variation in polarization states without relying on moving parts.

Example 53. The system of any of Examples 45-52, wherein said polarization state generator is configured to cycle through a plurality of polarization states.

Example 54. The system of any of Examples 45-53, wherein said polarization state generator is configured to cycle through elliptical polarization states.

Example 55. The system of any of Examples 45-54, wherein said polarization state generator is configured to cycle through a plurality of linear and elliptical polarization states.

Example 56. The system of any of Examples 45-55, wherein said polarization state generator is configured to cycle through a plurality of linear, elliptical, and circular polarization states.

Example 57. The system of any of Examples 45-56, wherein said polarization state generator is configured to cycle through different phase differences between orthogonal polarization states.

Example 58. The system of Example 57, wherein said phase differences extend over a range of at least 90°.

Example 59. The system of Example 57, wherein the phase differences extend over a range of at least 180°.

Example 60. The system of Example 57, wherein said polarization state generator is configured to cycle through a plurality of phase differences from 0 to π radians between orthogonal polarization states.

Example 61. The system of any of the Examples above, wherein said laser light source is configured to produce second harmonic generation (SHG) light from said sample.

Example 62. The system of any of the Examples above, configured to determine a characteristic of said sample based on measurements on second harmonic generation (SHG) light.

Example 63. The system of any of the Examples above, wherein said laser light source comprises a pulsed laser.

Example 64. The system of any of the Examples above, wherein said laser light source comprises a pulsed femtosecond laser.

Example 65. The system of any of the Examples above, wherein said laser light source is configured to output 20-100 femtosecond laser pulses.

Example 66. The system of any of the Examples above, wherein the laser light source has sufficiently high power to induce second harmonic generation in said sample.

Example 67. The system of any of the Examples above, wherein the laser light source output laser pulses having sufficiently high energy to induce second harmonic generation in said sample.

Example 68. The system of any of the Examples above, wherein said laser light source is configured to output laser pulses at a 1-100 MHz repetition rate.

Example 69. The system of any of the Examples above, wherein the laser light source outputs a polarized laser beam.

Example 70. The system of any of the Examples above, wherein the laser beam configured to be directed onto said sample comprises time-varying polarization states and phases of polarization components.

Example 71. The system of any of the Examples, included in-line of a semiconductor fabrication line.

Example 72. The system of any of the Examples above, wherein said at least one optical detector and said at least one retarder are configured to obtain at least four measurements to provide four parameters for characterizing the polarization state of said light from said sample.

Example 73. The system of any of the Examples above, the at least one optical detector comprises at least three detectors that generate the least three measurements in response of simultaneously receiving different portions of light produced as the result of said nonlinear optical effect.

Example 74. The optical metrology device of Example 73, wherein the three measured signals are generated in response to three different wavefront portions of nonlinearly generated light having different polarization states.

Example 75. The system of any of the Examples above, wherein the at least one optical detector comprises at least four detectors that generate the least four measurements in response of simultaneously receiving different portions of light produced as the result of said nonlinear optical effect.

Example 76. The optical metrology device of Example 74, wherein the four measured signals are generated in response of four different wavefront portions of nonlinearly generated light having different polarization states.

Example 77. The optical metrology device of any of the Examples above, wherein the at least one optical detector comprises at least three or at least four photodetector elements in a photodetector array and the at least three or at least four measured signals are generated by different ones of the at least three or at least four photodetector elements.

Example 78. The optical metrology device of Example 77, wherein the at least three or at least four measured signals are generated during a single readout period of the photodetector array.

Example 79. The optical metrology device of Example 77 or 78, wherein the at least three or at least four measured signals are generated in less than 20 milliseconds.

Example 80. The optical metrology device of Example 77-79, wherein the at least three or at least four measured signals measured signals are generated in less than 1 millisecond.

Example 81. The optical metrology device of any of the Examples above, wherein the detectors are included in a CCD detector array.

Example 82. The optical metrology device of any of Examples 1-80, wherein the photodetectors are included in a CMOS detector array.

Example 83. The optical metrology device of any of Examples 77-82, wherein the photodetector array is planar.

Example 84. The optical metrology device of any of Examples 77-82, wherein the at least three or at least four photodetector elements are fabricated on the same substrate.

Example 85. The optical metrology device of the Examples above, wherein said semiconductor wafer is included in a process for forming integrated circuits thereon.

Example 86. The optical metrology device of the Examples above, wherein said semiconductor wafer has integrated circuits formed thereon.

### Part 4-C

Example 1. A method of characterizing a sample, said method comprising:
for a sample comprising a semiconductor wafer in a process of having integrated circuits fabricated thereon, directing a laser beam comprising polarized laser light onto said sample thereby inducing a nonlinear optical effect and producing light from said sample as a result of said nonlinear optical effect;
varying the polarization state of the polarized laser light incident on said sample; and
performing ellipsometry measurements on said light from said sample for said varying polarization states of laser light incident on said sample.

Example 2. The method of Example 1, wherein said nonlinear optical effect comprises second harmonic generation (SHG), said laser light producing SHG light from said sample, said light from said sample on which said ellipsometry measurements are performed comprising SHG light.

Example 3. The method of Example 1 or 2, wherein said laser light directed onto said sample comprises pulsed laser light.

Example 4. The method of any the Examples above, wherein said laser light directed onto said sample comprises femtosecond pulses.

Example 5. The method of any the Examples above, wherein the laser light directed onto said sample has sufficiently high power to induce said nonlinear optical effect in said sample.

Example 6. The method of any the Examples above, wherein the laser light directed onto said sample comprises laser pulses having sufficiently high energy to induce second harmonic generation in said sample.

Example 7. The method of any the Examples above, wherein said laser light directed onto said sample comprises laser pulses at a 1-100 MHz repetition rate.

Example 8. The method of any the Examples above, wherein the laser beam directed onto said sample comprises time-varying polarization states and phases of polarization components.

Example 9. The method of any the Examples above, wherein varying the polarization states of light incident on said sample comprises providing a plurality of different polarization states to the light beam directed onto said sample by varying phase difference between orthogonal polarizations of the laser light incident on the sample.

Example 10. The method of any of the Examples above, wherein varying said polarization states comprises propagating said laser light through a retarder and rotating said retarder.

Example 11. The method of any of Examples 1-9, wherein varying said polarization states comprises propagating said laser light through a retarder and varying the retardance through said retarder.

Example 12. The method of any of Examples 1-9, wherein said polarization states are varied without relying on moving parts.

Example 13. The method of any of the Examples above, wherein said varying said polarization state comprises cycling through a plurality of polarization states.

Example 14. The method of any of the Examples above, wherein said varying said polarization state comprises cycling through elliptical polarization states.

Example 15. The method of any of the Examples above, wherein said varying said polarization state comprises cycling through a plurality of linear and elliptical polarization states.

Example 16. The method of any of the Examples above, wherein said varying said polarization state comprises cycling through a plurality of linear, elliptical, and circular polarization states.

Example 17. The method of any of the Examples above, wherein said varying said polarization state comprises cycling through different phase differences between orthogonal polarization states.

Example 18. The method of Example 18, wherein said phase differences extend over a range of at least 90°.

Example 19. The method of Example 18, wherein the phase differences extend over a range of at least 180°.

Example 20. The method of Example 18, comprising cycling through a plurality of phase differences from 0 to π radians between orthogonal polarization states.

Example 21. The method of any of the Example above, further comprising focusing the laser light beam onto said sample with a focusing lens.

Example 22. The method of any of the Examples above, further comprising collecting light from said sample with a lens.

Example 23. The method of any of the Examples above, wherein performing said ellipsometry measurements on said light from said sample includes measuring the amount of light transmitted through differently oriented linear polarizers.

Example 24. The method of any Example 24, wherein performing said ellipsometry measurements comprises measuring the amount of light transmitted through four differently oriented linear polarizers to obtain at least four different measurements respectively.

Example 25. The method of Example 24 or 25, wherein said differently oriented linear polarizers include linear polarizers orientated at 0°, 90°, 45°, 135°.

Example 26. The method of any of Examples 24-25, wherein said differently oriented linear polarizers include linear polarizers orientated horizontally, vertically, along a first diagonal, along a second diagonal opposite to the first diagonal.

Example 27. The method of any of the Examples above, wherein performing said ellipsometry measurements on said light from said sample includes measuring the amount of light transmitted through different combinations of retarders and differently oriented linear polarizers.

Example 28. The method of any of the Examples above, wherein performing said ellipsometry measurements on said light from said sample includes measuring the amount of light transmitted through different combinations of retarders and differently oriented linear polarizers to obtain at least four different measurements for determining at least four different parameters.

Example 29. The method of any of Examples 27 or 28, wherein said retarders comprises a half-wave retarder and quarter-wave retarder.

Example 30. The method of any of claims 27-29, wherein light from said sample is transmitted through at least one half-wave retarder paired with a plurality differently oriented linear polarizers and measured to obtain at least two respective measurements.

Example 31. The method of any of claims 27-30, wherein light from said sample is transmitted through at least one quarter-wave retarder paired with a plurality of differently oriented linear polarizers to obtain at least two respective measurements.

Example 32. The method of any of claims 27-31, wherein light from said sample is transmitted through a plurality of half-wave retarders paired with a plurality of four differently oriented linear polarizers, respectively, to obtain four respective measurements.

Example 33. The method of any of claims 27-32, wherein light from said sample is transmitted through a plurality of quarter-wave retarders paired with a plurality of four differently oriented linear polarizers, respectively, to obtain four respective measurements.

Example 34. The method of any of claims 27-33, wherein light from said sample is transmitted through a half-wave retarder paired with a linear polarizer orientated at 0°, a half-wave retarder paired with a linear polarizer orientated at 90°, a half-wave retarder paired with a linear polarizer orientated at 45°, and a half-wave retarder paired with a linear polarizer orientated at 135° to obtain four respective measurements.

Example 35. The method of any of claims 27-34, wherein light from said sample is transmitted through a quarter-wave retarder paired with a linear polarizer orientated at 0°, a quarter-wave retarder paired with a linear polarizer orientated at 90°, a quarter-wave retarder paired with a linear polarizer orientated at 45°, and a quarter-wave retarder paired with a linear polarizer orientated at 1350 to obtain four respective measurements.

Example 36. The method of any of Examples 27-35, wherein said retarders comprises a liquid crystal 2D phase array comprising a plurality of pixels comprising a plurality of respective retarders.

Example 37. The method of any of Examples 36, wherein said liquid crystal 2D phase array comprises a nematic 2D phase array.

Example 38. The method of Example 36 or 37, further comprising setting said liquid crystal 2D phase array pixels to half-wave and quarter-wave retardances.

Example 39. The method of any of claims 36-38, comprising setting said liquid crystal 2D phase array to an alternating pattern of pixels of half-wave and quarter-wave retardance.

Example 40. The method of any of claims 36-39, wherein light from said sample is transmitted through a half-wave retardance pixel paired with each of a plurality of four differently oriented linear polarizers to obtain four measurements.

Example 41. The method of any of claims 36-40, wherein light from said sample is transmitted through a quarter-wave retardance pixel paired with each of a plurality of four differently oriented linear polarizers to obtain four measurements.

Example 42. The method of any of claims 36-41, wherein light from said sample is transmitted through a half-wave retardance pixel paired with a linear polarizer orientated at 0°, a half-wave retardance pixel is paired with a linear polarizer orientated at 90°, a half-wave retardance pixel is paired with a linear polarizer orientated at 45°, and a half-wave retardance pixel is paired with a linear polarizer orientated at 135° to obtain four measurements.

Example 43. The method of any of claims 36-42, wherein light from said sample is transmitted through a quarter-wave retardance pixel is paired with a linear polarizer orientated at 0°, a quarter-wave retardance pixel is paired with a linear polarizer orientated at 90°, a quarter-wave retardance pixel is paired with a linear polarizer orientated at 45°, and a quarter-wave retardance pixel is paired with a linear polarizer orientated at 1350 to obtain four measurements.

Example 44. The method of Examples 36-43, wherein a plurality of optical detectors, a plurality of polarizers, and a plurality of retarders are arranged such that said plurality of optical detectors receives at least some light from said sample after passing through said plurality of retarders and said plurality of polarizers to obtain at least four separate measurements.

Example 45. The method of Examples 36-43, wherein a plurality of optical detectors, a plurality of polarizers, and a plurality of retarders are arranged such that said plurality of optical detectors receives at least some light from said sample after passing through said plurality of retarders and said plurality of polarizers to obtain at least eight separate measurements.

Example 46. The method of Examples 36-43, wherein a plurality of optical detectors, a plurality of polarizers, and a plurality of retarders are arranged such that said plurality of optical detectors receives at least some light from said sample after passing through said plurality of retarders and said plurality of polarizers to obtain at least four separate measurements for a plurality of spatial locations across a region of the sample from which said light is emitted.

Example 47. The method of Examples 36-43, wherein a plurality of optical detectors, a plurality of polarizers, and a plurality of retarders are arranged such that said plurality of optical detectors receives at least some light from said sample after passing through said plurality of retarders and said plurality of polarizers to obtain at least eight separate measurements for a plurality of spatial locations across a region of the sample on which the laser beam is incident.

Example 48. The method of any of the Examples above, further comprising using a first beamsplitter positioned to receive light from said sample and split said light into first and second arms.

Example 49. The method of Example 48, wherein said first beamsplitter comprises a partially polarizing beamsplitter.

Example 50. The method of Example 48 or 49, further comprising using a second beamsplitter in said first arm positioned to receive light from said first beamsplitter and split said light into two paths toward two separate detectors.

Example 51. The method of Example 50, wherein said second beamsplitter comprises a polarization beamsplitter.

Example 52. The method of Example 50 or 51, further comprising using a retarder in said first arm between said first and second beamsplitters.

Example 53. The method of Example 50 or 51, further comprising using a full wave retarder in said first arm between said first and second beamsplitters.

Example 54. The method of any of Examples 48-53, further comprising using a third beamsplitter in said second arm positioned to receive light from said first beamsplitter and split said light into two paths toward two separate detectors.

Example 55. The method of Example 54, wherein said third beamsplitter comprises a polarization beamsplitter.

Example 56. The method of Example 54 or 55, further comprising using a retarder in said second arm between said first and third beamsplitters.

Example 57. The method of Example 54 or 55, further comprising using a quarter wave retarder in said second arm between said first and third beamsplitters.

Example 58. The method of Example 44-57, wherein said plurality of detectors comprises a plurality of photomultiplier tubes (PMT).

Example 59. The method of any of the Examples above, wherein said measurements provide information for determining four Stokes parameters, S0, S1, S2, S3.

Example 60. The method of any of the Examples above, further comprising determining four Stokes parameters, S0, S1, S2, S3 from said measurements.

Example 61. The method of any of the Examples above, wherein said measurements provides information for determining a Stokes vector.

Example 62. The method of any of the Examples above, further comprising determining a Stokes vector from said measurements.

Example 63. The method of Example 61 or 62, wherein a nonlinear susceptibility tensor can be derived from said Stokes vector.

Example 64. The method of Example 61 or 62, further comprising a nonlinear determining a susceptibility tensor form said Stokes vector.

Example 65. The method of Example 59 or 60, wherein a nonlinear susceptibility tensor can be derived from said Stokes parameters.

Example 66. The method of Example 59 or 60, further comprising deriving a nonlinear susceptibility Tensor from said Stokes parameters or Stokes vector.

Example 67. The method of any of Examples 63-66, wherein a Mueller Matrix (polarization state matrix) can be derived from said nonlinear susceptibility tensor.

Example 68. The method of any of Examples 63-66, further comprising deriving a Mueller Matrix from said nonlinear susceptibility tensor.

Example 69. The method of any of the Examples 1-8 or 21-68, wherein varying the polarization state of the laser light incident on said sample comprise forming a polarization vortex beam from said laser beam.

Example 70. The method of Examples 69, further comprising directing said laser beam to a q-plate and a retarder configured to produce a polarization vortex beam that is incident on said sample.

Example 71. The method of Example 69, further comprising directing said laser beam to a q-plate and a retarder positioned to receive said laser beam from said laser light source so as to produce a polarization vortex beam having a plurality of different polarization states across a cross-section of the vortex beam orthogonal to the propagation direction of the vortex beam.

Example 72. The method of Example 70 or 71, wherein further comprising rotating said retarder to change the polarization states in the vortex beam.

Example 73. The method of any of the Examples 69-72, wherein said polarization vortex beam has an orbital angular momentum and different polarization states across a cross-section of the beam orthogonal to the propagation of the beam.

Example 74. The method of any of the Examples 70-73, wherein said retarder comprises a quarter wave retarder.

Example 75. The method of any of Examples 70-74, wherein said q-plate comprises a refractive or Fresnel element, meta surface or diffraction grating.

Example 76. The method of any of Examples 70-74, wherein said q-plate comprises a spatial light modulator comprising a plurality of pixels that can be modulated.

Example 77. The method of Example 76, further comprising setting the pixels of said spatial light modulator to produce said vortex beam.

Example 78. The method of Examples 76 or 77, further comprising setting the pixels of said spatial light modulator to form a diffraction pattern with said pixels of said spatial light modulator.

Example 79. The method of Example 78, wherein said diffraction pattern comprises a forked grating.

Example 80. The method of any of Examples 76-79, wherein said spatial light modulator comprising said q-plate comprises a liquid crystal spatial light modulator.

Example 81. The method of any of Examples 76-80, wherein said spatial light modulator comprises a phase spatial light modulator and said method further comprises forming a grating with said intensity spatial light modulator to vary the phase of light transmitted through or reflected from said pixels of said spatial light modulator to produce said vortex beam.

Example 82. The method of any of Examples 76-81, further comprising interfering said laser light from said laser light source that is directed to said spatial light modulator comprising said q-plate with laser light that is transmitted through or reflected from said spatial light modulator.

Example 83. The method of any of Examples 82, further comprising adjusting a q-plate based on said interference pattern.

Example 84. The method of any of Examples 82, further comprising adjusting a spatial light modulator comprising a q-plate based on said interference pattern.

Example 85. The method of any of Examples 82-84, further comprising adjusting a spatial light modulator based on said interference pattern, said spatial light modulator positioned to receive said laser beam prior to said sample receiving said laser beam.

Example 86. The method of any of Examples 82-85, further comprising controlling said spatial light modulator to alter the state of pixels in the spatial light modulator based on said interference pattern.

Example 87. The method of any of the Examples above, further comprising positioning a reflector where said sample would be located and interfering said laser beam directed toward said reflector with the light reflected from said reflector.

Example 88. The method of any of the Examples above, further comprising imaging an interference pattern formed by interfering said laser beam directed toward said reflector with the light reflected from said reflector.

Example 89. The method of any of Examples 82-88, further comprising performing alignment adjustments based on said interference pattern.

Example 90. The method of any of the Examples above, wherein said laser beam is directed onto said sample and said ellipsometry measurements are performed on said light from said sample when said wafer is in-line of a semiconductor fabrication line.

Example 91. The method of any of Examples 1-90, wherein said semiconductor wafer is transferred from a first fabrication or measurement or characterization station in a fabrication line to second station in said fabrication line where said laser beam is directed onto said sample and said ellipsometry measurements are performed on said light from said sample, and said semiconductor wafer is transferred from said second station to third fabrication or measurement or characterization station in said fabrication line.

Example 92. The method of any of Examples 1-90, wherein said semiconductor wafer is transferred from a fabrication station or measurement or characterization station in a fabrication line to another station in said fabrication line where said laser beam is directed onto said sample and said ellipsometry measurements are performed on said light from said sample, and said semiconductor wafer is transferred from said station where said ellipsometry measurements are performed back to said fabrication station or measurement or characterization station.

Example 93. The method of any of Examples 1-90, wherein said semiconductor wafer is transferred from a first fabrication or measurement or characterization station in a fabrication line for fabricating integrated circuits on said semiconductor wafer to second station in said fabrication line where said laser beam is directed onto said sample and said ellipsometry measurements are performed on said light from said sample, and said semiconductor wafer is transferred from said second station to third fabrication or measurement or characterization station in said fabrication line to resume fabrication of integrated circuits on said semiconductor wafer.

Example 94. The method of any of Examples 1-90, wherein said semiconductor wafer is transferred from a fabrication station or measurement or characterization station in a fabrication line for fabricating integrated circuits on said semiconductor wafer to another station in said fabrication line where said laser beam is directed onto said sample and said ellipsometry measurements are performed on said light from said sample, and said semiconductor wafer is transferred from said station where said ellipsometry measurements are performed back to said fabrication station or measurement or characterization station to resume fabrication of integrated circuits on said semiconductor wafer.

### Part-5

Example 1. A sample characterization system for interrogating a sample, said system comprising:
a laser light source configured to output a laser beam to be directed to said sample such that light emanates from said sample;
polarization optics positioned to receive the laser beam output by the laser light source to provide one or more polarization states to said light beam that is incident on said sample;
at least one optical detector and at least one retarder positioned such that said at least one optical detector receives at least some of said light from said sample after passing through said at least one retarder; and
first and second beamsplitters and a sensor array configured to receive light from said first and second beamsplitters to detect an interference pattern formed from said light from said first and second beamsplitters.

Example 2. The system of Example 1, wherein said first beamsplitter is positioned in an optical path between said laser light source and said sample.

Example 3. The system of Example 1 or 2, wherein said sample is in an optical path between said first and second beamsplitters.

Example 4. The system of any of the Examples above, wherein a reflector at a location of said sample reflects said light beam from said light source such that said second beamsplitter receives said reflected light beam and a portion of said reflected light beam is received by said sensor array.

Example 5. The system of Example 4, wherein said reflector is in an optical path between said first and second beamsplitters.

Example 6. The system of Examples 4 or 5, wherein said first beamsplitter is positioned in an optical path between said laser light source and said reflector.

Example 7. The system of any of Examples 4-6, wherein said first beamsplitter is positioned in an optical path between said laser light source and said sample.

Example 8. The system of any of Examples 4-7, wherein said reflector at a location of said sample reflects said light beam from said light source such that light reflected from said reflector is interfered at said sensor array with a portion of said laser beam prior to being reflected by said reflector.

Example 9. The system of any of Examples 4-8, wherein said second beamsplitter receives said reflected light beam and a portion of said reflected light beam is received by said sensor array.

Example 10. The system of any of any of the Examples above, further comprising a spatial light modulator in an optical path between laser light source and said sample and electronics in communication with said sensor array and said spatial light modulator to adjust said spatial light modulator based on said interference pattern.

Example 11. The system of any of the Examples above, wherein said laser light source is configured to produce a nonlinear output from said sample.

Example 12. The system of any of the Examples above, wherein said laser light source is configured to produce SHG light from said sample.

Example 13. The system of any of the Examples above, wherein said laser light source comprises a pulsed femtosecond laser.

Example 14. The system of any of the Examples above, wherein the laser light source has sufficiently high power to induce second harmonic generation in said sample.

Example 15. The system of any of the Examples above, wherein the laser light source outputs laser pulses having sufficiently high energy to induce second harmonic generation in said sample.

Example 16. The system of any of the Examples above, wherein said laser light source is configured to output laser pulses at a 1-100 MHz repetition rate.

### Part-6

Example 1. A sample characterization system configured to interrogate a sample, said system comprising:
a laser light source configured to output a laser beam to be directed to said sample, said laser beam having sufficient energy to induce a nonlinear optical effect and produce light from said sample as a result of said nonlinear optical effect;
at least one optical detector positioned to receive at least some of the light from said sample produced by said nonlinear optical effect; and
an atomic force microscope (AFM) that can be positioned with respect to said sample to perform one or more measurements from said sample and/or image said sample.

Example 2. The system of Example 1, wherein said laser light source is configured to produce SHG light from said sample.

Example 3. The system of Example 1 or 2, wherein said laser light source comprises a pulsed femtosecond laser.

Example 4. The system of any of the Examples above, wherein the laser light source has sufficiently high power to induce second harmonic generation in said sample.

Example 5. The system of any of the Examples above, wherein the laser light source outputs laser pulses having sufficiently high energy to induce second harmonic generation in said sample.

Example 6. The system of any of the Examples above, wherein said laser light source is configured to output laser pulses at a 1-100 MHz repetition rate.

Example 7. The system of any of the Examples above, wherein said AFM comprises an AFM tip configured to come in proximity with the sample.

Example 8. The system of any of the Examples above, wherein said AFM tip is configured to obtain an assessment of charge on a portion of said sample.

Example 9. The system of any of the Examples above, wherein said AFM tip is configured to obtain an measurement of charge on a portion of said sample.

Example 10. The system of any of the Examples above, wherein said AFM tip is configured to be scanned across a portion of said sample.

Example 11. The system of any of the Examples above, further comprising a corona gun that can be positioned to deposit charge on said sample.

### Terminology

Conditional language, such as “can,” “could,” “might,” or “may,” unless specifically stated otherwise, or otherwise understood within the context as used, is generally intended to convey that certain embodiments include, while other embodiments do not include, certain features, elements, and/or steps. Thus, such conditional language is not generally intended to imply that features, elements, and/or steps are in any way required for one or more embodiments.

Conjunctive language such as the phrase “at least one of X, Y, and Z,” unless specifically stated otherwise, is to be understood within the context used in general to convey that an item, term, etc. may be either X, Y, or Z. Thus, such conjunctive language is not generally intended to imply that certain embodiments require the presence of at least one of X, at least one of Y, and at least one of Z.

Language of degree, as used herein, such as the terms “approximately,” “about,” “generally,” and “substantially,” represent a value, amount, or characteristic close to the stated value, amount, or characteristic that still performs a desired function or achieves a desired result. For example, the terms “approximately,” “about,” “generally,” and “substantially” may refer to an amount that is within ±10% of, within ±5% of, within ±2% of, within ±1% of, or within ±0.1% of the stated amount. As another example, the terms “generally parallel” and “substantially parallel” refer to a value, amount, or characteristic that departs from exactly parallel by ±10 degrees, by ±5 degrees, by ±2 degrees, by ±1 degree, or by ±0.1 degree, and the terms “generally perpendicular” and “substantially perpendicular” refer to a value, amount, or characteristic that departs from exactly perpendicular by ±10 degrees, by ±5 degrees, by ±2 degrees, by ±1 degree, or by ±0.1 degree.

Various configurations have been described above. Although this invention has been described with reference to these specific configurations, the descriptions are intended to be illustrative of the invention and are not intended to be limiting. Various modifications and applications may occur to those skilled in the art without departing from the true spirit and scope of the invention. Thus, for example, in any method or process disclosed herein, the acts or operations making up the method/process may be performed in any suitable sequence and are not necessarily limited to any particular disclosed sequence. Features or elements from various embodiments and examples discussed above may be combined with one another to produce alternative configurations compatible with embodiments disclosed herein. Various aspects and advantages of the embodiments have been described where appropriate. It is to be understood that not necessarily all such aspects or advantages may be achieved in accordance with any particular embodiment. Thus, for example, it should be recognized that the various embodiments may be carried out in a manner that achieves or optimizes one advantage or group of advantages as taught herein without necessarily achieving other aspects or advantages as may be taught or suggested herein.

1. A sample characterization system for interrogating a sample, said system comprising:
a laser light source configured to output a laser beam to be directed to said sample such that light emanates from said sample;
a polarization state generator positioned to receive the laser beam output by the laser light source to provide a plurality of different polarization states to said laser light beam that is incident on said sample; and
a detector array comprising a plurality of detectors having differently oriented linear polarizers in front of different detectors and a plurality of retarders disposed in front of said differently oriented linear polarizers such that said light emanated from said sample passes through said plurality of retarders, said differently oriented linear polarizers, and to said plurality of detectors.

2. The system of claim 1, wherein said laser light source is configured such that said light emanated from said sample comprises nonlinearly generated light.

3. The system of claim 1, wherein said laser light source is configured to produce second harmonic generation (SHG) light from said sample.

4. (canceled)

5. The system of claim 1, wherein said polarization state generator comprises a retarder configured to be varied to vary phase differences introduced in orthogonal polarizations passing through the retarder.

6. (canceled)

7. The system of claim 1, wherein said polarization state generator comprises a photoelastic modulator.

8. The system of claim 1, wherein said polarization state generator is configured to provide variation in polarization states without relying on moving parts.

9. (canceled)

10. The system of claim 1, wherein said differently oriented linear polarizers include linear polarizers orientated at 0°, 90°, 45°, 135° with respect to rows of detectors in said detector array.

11. The system of claim 1, wherein said differently oriented linear polarizers include linear polarizers orientated horizontally, vertically, along a first diagonal, and along a second diagonal opposite to the first diagonal with respect to rows of detectors in said detector array.

12. The system of claim 1, wherein said detector array is included in a polarization sensing camera (PSC).

13. The system of claim 1, wherein at least one retarder of the plurality of retarders comprises a plurality of half-wave retarders and quarter-wave retarders.

14. The system of claim 1, wherein a half-wave retarder is paired with each of a plurality of four differently oriented linear polarizers.

15. The system of claim 1, wherein a quarter-wave retarder is paired with each of a plurality of four differently oriented linear polarizers.

16. The system of claim 1, wherein said plurality of retarders comprises a liquid crystal 2D phase array comprising a plurality of retarders.

17. The system of claim 16, wherein said liquid crystal 2D phase array comprises pixels configured to be set to half-wave and quarter-wave retardance.

18. The system of claim 1, wherein a half-wave retardance pixel is paired with each of a plurality of four differently oriented linear polarizers.

19. The system of claim 1, wherein a quarter-wave retardance pixel is paired with each of a plurality of four differently oriented linear polarizers.

20. The system of claim 1, wherein signals from said plurality of detectors provide information for determining a Stokes vector.

21. The system of claim 1, wherein signals from said plurality of detectors provide information for determining four Stokes parameters, S₀, S₁, S₂, S₃.

22. (canceled)

23. (canceled)

24. The system of claim 20, wherein a nonlinear susceptibility tensor can be derived from said Stokes vector and a Mueller Matrix can be derived from said nonlinear susceptibility tensor.

25. The system of claim 1, included in-line of a semiconductor fabrication line.

26. (canceled)
